(19) United States
(12) Patent Application Publication
(10) Pub. No.: US 2024/0178358 A1
(43) Pub. Date: May 30, 2024

(54) DISPLAY DEVICE AND METHOD OF MANUFACTURING THE SAME

(71) Applicant: LG Display Co., Ltd., Seoul (KR)

(72) Inventors: HyeSeon EOM, Seoul (KR); DaeYoung SEO, Seoul (KR); JuHyun NAM, Seoul (KR)

(73) Assignee: LG Display Co., Ltd., Seoul (KR)

(21) Appl. No.: 18/134,305

(22) Filed: Apr. 13, 2023

(30) Foreign Application Priority Data
Nov. 29, 2022 (KR) 10-2022-0162801

(51) Int. Cl. H01L 33/62; G09F 9/302; G09F 9/33; G09G 3/32; H01L 25/075; H01L 25/16; H01L 27/12

(52) U.S. Cl. CPC H01L 33/62; G09F 9/3026; G09F 9/33; G09G 3/32; H01L 25/0753; H01L 25/167; H01L 27/124; G09G 2310/0267; H01L 2933/0016; H01L 2933/0066

(57) ABSTRACT

A display device can include a display panel having an display area and a dummy area surrounding the display area, a plurality of sub-pixels disposed in the display area, a plurality of dummy sub-pixels disposed in the dummy area, a pixel circuit disposed in the plurality of sub-pixels, and at least a pair of low potential power supply lines disposed in each of the plurality of sub-pixels and the plurality of dummy sub-pixels. Therefore, it is possible to reduce or minimize transfer issues of light emitting elements in an outer portion of the display area by forming the low potential power supply lines for self-assembling the light emitting element in the dummy area.

### CROSS-REFERENCE TO RELATED APPLICATIONS

This application claims priority to Korean Patent Application No. 10-2022-0162801 filed on Nov. 29, 2022, in the Republic of Korea, the entire contents of which are hereby expressly incorporated by reference into the present application.

### BACKGROUND

### Technical Field

The present disclosure relates to a display device and a method of manufacturing the display device, and more particularly, for example, without limitation, to a display device in which light emitting diodes (LEDs) are self-assembled and a method of manufacturing such display device.

### Discussion of the Related Art

Display devices used in computer monitors, TVs, and mobile phones can include organic light emitting displays (OLEDs) that emit light by themselves, and liquid crystal displays (LCDs) that require a separate light source.

Display devices are being applied to various fields of application including not only computer monitors and TVs, but also personal mobile devices. As such, display devices having a reduced volume and a light weight while having a wide display area are being studied and developed.

In recent years, display devices including light emitting diodes (LEDs) have received attention as the next-generation display devices. Since the LED is formed of an inorganic material rather than an organic material, it has excellent reliability and has a longer lifespan compared to a liquid crystal display or an organic light emitting display. In addition, the LED has a high lighting speed, high luminous efficiency and excellent stability due to high impact resistance and can display a high-luminance image.

The description provided in the description of the related art section should not be assumed to be prior art merely because it is mentioned in or associated with the description of the related art section. The description of the related art section can include information that describes one or more aspects of the subject technology.

### SUMMARY OF THE DISCLOSURE

The inventors have recognized needs described above and limitations associated with the related art. Accordingly, an aspect of the present disclosure is to provide a display device having an improved self-assembling rate of light emitting elements and a method of manufacturing the display device.

Another aspect of the present disclosure is to provide a display device in which a transfer failure or transfer issue of light emitting elements in an outer portion of an display area can be reduced or eliminated and a method of manufacturing the display device.

Still another aspect of the present disclosure is to provide a display device in which an imbalance in electric fields for self-assembling of light emitting elements, which may occur, can be compensated in the entirety of a display panel by forming assembly electrodes and openings even in a non-display area of the display panel.

It is to be understood that objects of the present disclosure are not limited to the above-mentioned objects, and other objects, which are not mentioned above, can be clearly understood by those skilled in the art from the following descriptions.

A display device according to an exemplary embodiment of the present disclosure can include a substrate including an display area and a dummy area surrounding the display area; a plurality of sub-pixels disposed in the display area; a plurality of dummy sub-pixels disposed in the dummy area; a pixel circuit disposed only in the plurality of sub-pixels among the plurality of sub-pixels and the plurality of dummy pixels; and a pair of low potential power supply lines disposed in each of the plurality of sub-pixels and the plurality of dummy sub-pixels. Therefore, it is possible to reduce or minimize a transfer failure or transfer issue of light emitting elements in an outer portion of the display area by forming the low potential power supply lines for self-assembling the light emitting element in the dummy area surrounding the display area.

A method of manufacturing a display device according to an exemplary embodiment of the present disclosure can include forming a pair of assembly electrodes in each of a plurality of sub-pixels in an display area of a substrate and a plurality of dummy sub-pixels in a dummy area extending from the display area; forming an organic layer having a plurality of openings on the pair of assembly electrodes in each of the plurality of sub-pixels and the plurality of dummy sub-pixels; and self-assembling a light emitting element in an opening disposed in each of the plurality of sub-pixels among the plurality of openings, wherein the self-assembling of the light emitting element includes forming electric fields by applying a voltage to the pair of assembly electrodes disposed in the display area and the dummy area. Accordingly, the plurality of openings and a plurality of the assembly electrodes are formed in the dummy area outside the display area, so that outermost openings where electric fields for self-assembling of the light emitting elements are non-uniformly formed cannot be or may not be formed in the display area.

Other detailed matters of the exemplary embodiments are included in the detailed description and the drawings.

According to the present disclosure, a yield of the display device can be increased by improving a self-assembling rate of light emitting elements.

According to the present disclosure, it is possible to reduce or minimize a transfer failure or transfer issue of light emitting elements in an outer portion of a display area of the display device.

According to the present disclosure, light emitting elements can be stably self-assembled by compensating for imbalance in electric fields.

According to the present disclosure, production energy used to produce the display device can be reduced by optimizing a transfer process of light emitting elements.

It is to be understood that the effects according to the present disclosure are not limited to the contents exemplified above, and more various effects are included in the present specification.

### BRIEF DESCRIPTION OF THE DRAWINGS

The above and other objectives, features, and advantages of the present disclosure will be more clearly understood from the following detailed description, taken in conjunction with the accompanying drawings, in which:

FIG. 1 is a schematic configuration diagram of a display device according to an exemplary embodiment of the present disclosure.

FIG. 2A is a partial cross-sectional view of the display device according to an exemplary embodiment of the present disclosure.

FIG. 2B is a perspective view of a tiling display device according to an exemplary embodiment of the present disclosure.

FIG. 3 is a plan view of a display panel of the display device according to an exemplary embodiment of the present disclosure.

FIG. 4 is an enlarged plan view of a display area of the display device according to an exemplary embodiment of the present disclosure.

FIG. 5 is a cross-sectional view taken along line A-A′ and line B-B′ of FIG. 4.

FIG. 6 is an enlarged plan view of a dummy area of the display device according to an exemplary embodiment of the present disclosure.

FIG. 7 is a cross-sectional view taken along line C-C′ and line D-D′ of FIG. 6.

FIGS. 8A and 8B are cross-sectional views for illustrating a method of manufacturing the display device according to an exemplary embodiment of the present disclosure.

FIGS. 9A and 9B are examples of simulation results obtained by measuring electric fields formed by a plurality of assembly electrodes.

FIG. 10 is a cross-sectional view of a dummy area of a display device according to another exemplary embodiment of the present disclosure.

FIG. 11 is a cross-sectional view for explaining a method of manufacturing the display device according to another exemplary embodiment of the present disclosure.

FIG. 12 is a cross-sectional view of a dummy area of a display device according to still another exemplary embodiment of the present disclosure.

FIG. 13 is a plan view of a display panel of a display device according to still another exemplary embodiment of the present disclosure.

FIGS. 14A and 14B are cross-sectional views taken along line E-E′ of FIG. 13.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

The shapes, sizes, areas, ratios, angles, numbers, and the like disclosed in the accompanying drawings for describing the exemplary embodiments of the present disclosure can be merely examples, and the present disclosure is not limited thereto. Like reference numerals generally denote like elements throughout the specification. Further, in the following description of the present disclosure, a detailed explanation of known related technologies can be omitted or can be briefly provided to avoid unnecessarily obscuring the subject matter of the present disclosure. The terms such as “including,” “contain,” “constitute,” “make up of,” “formed of,” and “having” used herein are generally intended to allow other components to be added unless the terms are used with the term such as “only”. Any references to singular can include plural unless expressly stated otherwise.

In the analysis of a component, it shall be understood that an error range or tolerance range is included therein, even in the situation in which there is no explicit description thereof.

When the position relation between two parts is described using the terms such as “on”, “over”, “above”, “below”, “under”, “beside”, “beneath”, “near”, “close to”, “adjacent to”, “next to”, “on a side of” or the like, one or more parts can be positioned between the two parts unless the terms are used with the term such as “immediately,” “close(ly) or “directly”.

When an element or layer is disposed “on” another element or layer, one or more other layers or elements can be interposed directly on the other element or therebetween.

When temporally relative terms, such as “after”, “subsequent”, “following”, “next” and “before” are used to define a temporal relationship, a non-continuous case can be included unless the a more limiting term such as “immediately”, “just”, or “directly” is used.

Although the terms “first”, “second”, “A”, “B”, “(a)”, and “(b)” and the like are used for describing various components, these components are not confined by these terms. These terms are merely used for distinguishing one component from the other components. Therefore, a first component to be mentioned below can be a second component in a technical concept of the present disclosure.

In addition, terms, such as first, second, A, B, (a), or (b), can be used herein when describing components of the present disclosure. Each of these terminologies is not used to define an essence, order, or sequence of a corresponding component but used merely to distinguish the corresponding component from other components. In the case that it is described that a certain structural element or layer is “connected”, “coupled”, “adhered” or “joined” to another structural element or layer, it is typically interpreted that another structural element or layer can be “connected”, “coupled”, “adhered” or “joined” to the structural element or layer directly or indirectly.

A term “at least one” is typically understood as including any and all combinations of one or more of the associated components. For example, the meaning of “at least one of a first item, a second item, and a third item” denotes a combination of two or more components of the first component, the second component, and the third component as well as each individual component, the first component, the second component, or the third component.

A term “device” used herein can refer to a display device/apparatus including a display panel and a driver for driving the display panel. Examples of the display device can include a light emitting diode (LED), and the like. In addition, examples of the device can include a notebook computer, a television, a computer monitor, an automotive device, wearable device, and an automotive equipment device, and a set electronic device (or apparatus) or a set device (or apparatus), for example, a mobile electronic device such as a smartphone or an electronic pad, which are complete products or final products respectively including LED and the like, but embodiments of the present disclosure are not limited thereto.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Hereinafter, a display device and a method of manufacturing the display device according to exemplary embodiments of the present disclosure will be described in detail with reference to accompanying drawings.

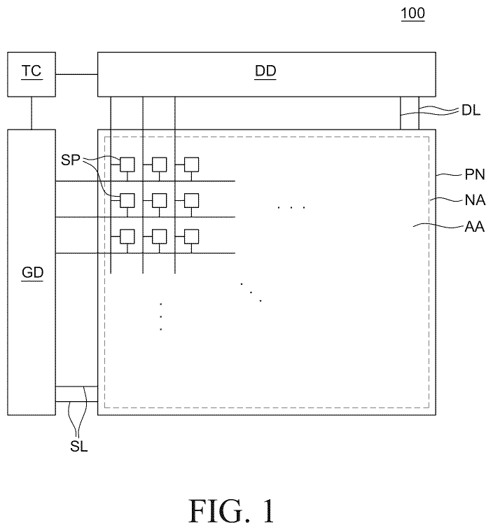

FIG. 1 is a schematic configuration diagram of a display device according to an exemplary embodiment of the present disclosure. All the components of each display device according to all embodiments of the present disclosure are operatively coupled and configured. In FIG. 1, a display panel PN, a gate driver GD, a data driver DD, and a timing controller TC among various components of a display device 100 are illustrated for convenience of description, but embodiments of the present disclosure are not limited thereto and the display device of the present disclosure includes other components.

Referring to FIG. 1, the display device 100 includes the display panel PN including a plurality of sub-pixels SP, the gate driver GD and the data driver DD for supplying various signals to the display panel PN, and the timing controller TC for controlling the gate driver GD and the data driver DD.

The gate driver GD supplies a plurality of scan signals to a plurality of scan lines SL according to a plurality of gate control signals provided from the timing controller TC. Although it is illustrated in FIG. 1 that one gate driver GD is disposed to be spaced apart from one side of the display panel PN, the number and arrangement of gate drivers GD are not limited thereto, for example, gate driver GDs can be disposed on both sides of the display panel PN.

The data driver DD supplies data voltages to a plurality of data lines DL according to a plurality of data control signals and image data provided from the timing controller TC. The data driver DD can convert image data into data voltages using a reference gamma voltage and supply the converted data voltages to the plurality of data lines DL.

The timing controller TC aligns image data input from the outside and supplies it to the data driver DD. The timing controller TC can generate a gate control signal and a data control signal using synchronization signals input from the outside, for example, a dot clock signal, a data enable signal, and a horizontal/vertical synchronization signal. In addition, the timing controller TC can supply the generated gate control signal and data control signal to the gate driver GD and the data driver DD, respectively, to thereby control the gate driver GD and the data driver DD.

The display panel PN, a component for displaying an image to a user, includes the plurality of sub-pixels SP. In the display panel PN, the plurality of scan lines SL and the plurality of data lines DL cross each other, and each of the plurality of sub-pixels SP can be formed at intersections of the scan lines SL and the data lines DL.

A display area (active area) AA and a non-display area (non-active area) NA surrounding or adjacent to the display area AA can be defined in the display panel PN.

The display area AA is an area in which an image is displayed in the display device 100. The plurality of sub-pixels SP constituting a plurality of pixels PX and a circuit for driving the plurality of sub-pixels SP can be disposed in the display area AA. The plurality of sub-pixels SP are minimum units constituting the display area AA, and n sub-pixels SP can constitute one pixel PX, where for example, n≥3. A thin film transistor or the like for driving a plurality of light emitting elements 130 can be disposed in each of the plurality of sub-pixels SP. The plurality of light emitting elements (130 in later figures) can be differently defined according to a type of display panel PN. For example, when the display panel PN is an inorganic light emitting display panel PN, the light emitting element 130 can be a light emitting diode (LED) or a micro-light emitting diode (LED), but embodiments of the present disclosure are not limited thereto.

A plurality of signal lines for transmitting various signals to the plurality of sub-pixels SP are disposed in the display area AA. For example, the plurality of signal lines can include a plurality of data lines DL for supplying data voltages to each of the plurality of sub-pixels SP, a plurality of scan lines SL for supplying gate voltages to each of the plurality of sub-pixels SP, and the like. The plurality of scan lines SL can extend in one direction in the display area AA and be connected to the plurality of sub-pixels SP, and the plurality of data lines DL can extend in a direction different from the one direction in the display area AA and be connected to the plurality of sub-pixels SP. In addition, low potential power supply lines, high potential power supply lines, and the like can be further disposed in the display area AA, but embodiments of the present disclosure are not limited thereto.

The non-display area NA is an area in which an image is not displayed and can be defined as an area extending from the display area AA. In the non-display area NA, pad electrodes and link lines for transmitting signals to the sub-pixels SP of the display area AA, or driving ICs (integrated circuits) such as gate driver ICs, data driver ICs and timing controller IC can be disposed.

Meanwhile, the non-display area NA can be positioned on a rear surface of the display panel PN, for example, a surface without the sub-pixel SP, or can be omitted, and is not limited to that in the drawings.

Meanwhile, driving units such as the gate driver GD, the data driver DD, and the timing controller TC can be connected to the display panel PN in various manners. For example, the gate driver GD can be mounted in a gate in panel (GIP) method in the non-display area NA, or mounted in a gate in display area (GIA) method between the plurality of sub-pixels SP in the display area AA.

For example, the data driver DD and the timing controller TC are formed on a separate flexible film and printed circuit board, and the data driver DD and the timing controller TC can be electrically connected to the display panel PN in a method of bonding the flexible film and the printed circuit board to pad electrodes formed in the non-display area NA of the display panel PN.

Alternatively, when the gate driver GD is mounted within the display area AA using the GIA method, and the flexible film and the printed circuit board are bonded to the rear surface of the display panel PN by forming side lines SRL connecting signal lines on a front surface of the display panel PN to the pad electrodes on the rear surface of the display panel PN, the non-display area NA on the front surface of the display panel PN can be maximally reduced.

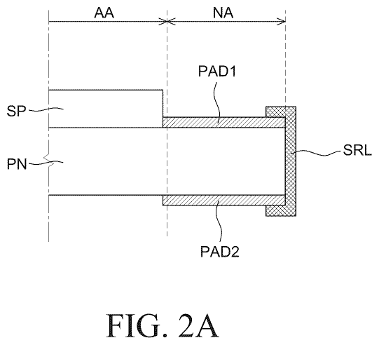

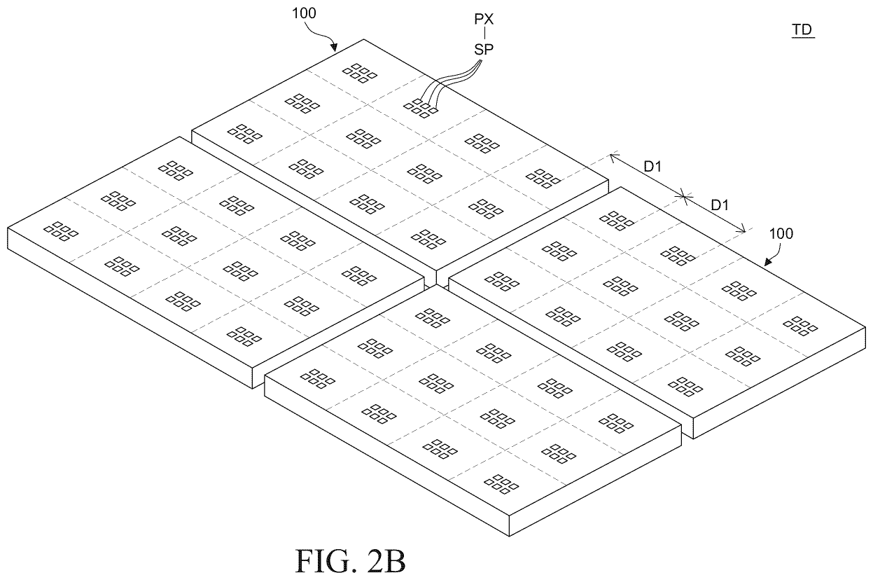

Accordingly, when the gate driver GD, the data driver DD, and the timing controller TC are connected to the display panel PN in the above manner, it is possible to realize a zero-bezel substantially without a bezel. FIGS. 2A and 2B will be referred for a more detailed description.

FIG. 2A is a partial cross-sectional view of the display device according to an exemplary embodiment of the present disclosure. FIG. 2B is a perspective view of a tiling display device according to an exemplary embodiment of the present disclosure.

A plurality of the pad electrodes are disposed in the non-display area NA of the display panel PN to transmit various signals to the plurality of sub-pixels SP. For example, in the non-display area NA on the front surface of the display panel PN, a first pad electrode PAD1 for transmitting signals to the plurality of sub-pixels SP is disposed, and a second pad electrode PAD2 electrically connected to driving components such as the flexible film and the printed circuit board is disposed in the non-display area NA on the rear surface of the display panel PN.

In this case, various signal lines connected to the plurality of sub-pixels SP, for example, scan lines SL, data lines DL and the like can extend from the display area AA to the non-display area NA and be electrically connected to the first pad electrode PAD1.

In addition, the side line SRL is disposed along a side surface of the display panel PN. The side line SRL can electrically connect the first pad electrode PAD1 on the front surface of the display panel PN and the second pad electrode PAD2 on the rear surface of the display panel PN. Accordingly, signals from driving components on the rear surface of the display panel PN can be transferred to the plurality of sub-pixels SP through the second pad electrode PAD2, the side line SRL, and the first pad electrode PAD1. Accordingly, the area of the non-display area NA of the display panel PN can be reduced or minimized by forming signal transmission paths from the front surface to the side surface and the rear surface of the display panel PN.

Referring to FIG. 2B, a tiling display device TD having a large screen can be implemented by connecting a plurality of display devices 100. In this case, when the tiling display device TD is implemented using the display devices 100 with a reduced or minimized bezel as illustrated in FIG. 2A, a seam area in which an image is not displayed between the display devices 100 is reduced or minimized, so that display quality can be improved.

For example, the plurality of sub-pixels SP can constitute one pixel PX. A distance D1 between an outermost pixel PX of one display device 100 and an outermost pixel PX of another display device 100 adjacent thereto can be implemented to be equal to a distance D1 between the pixels PX in one display device 100. Accordingly, the distance of the pixels PX between the display devices 100 is configured to be constant, so that the seam area can be reduced or minimized.

However, FIGS. 2A and 2B are exemplary, and the display device 100 according to an exemplary embodiment of the present disclosure can be a general display device 100 having a bezel, but is not limited thereto.

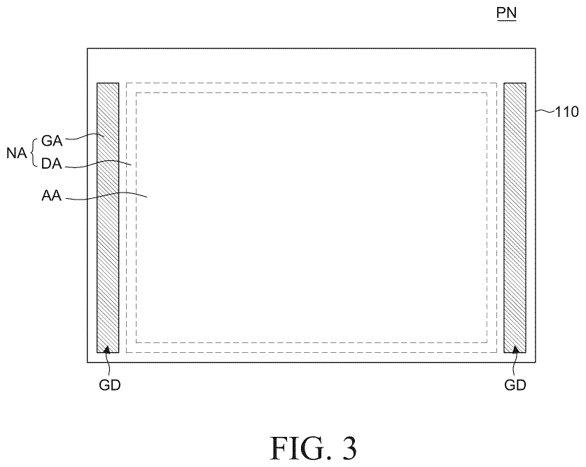

Hereinafter, the display panel PN of the display device 100 according to an exemplary embodiment of the present disclosure will be described in more detail with reference to FIGS. 3 to 7.

FIG. 3 is a plan view of a display panel of the display device according to an exemplary embodiment of the present disclosure.

Referring to FIG. 3, as described above, the display panel PN includes the display area AA in which the plurality of sub-pixels SP are disposed to display an image, and the non-display area NA extending from the display area AA and having various driving circuits for driving the plurality of sub-pixels SP, disposed therein. In this case, the non-display area NA includes a dummy area DA and gate driving areas GA.

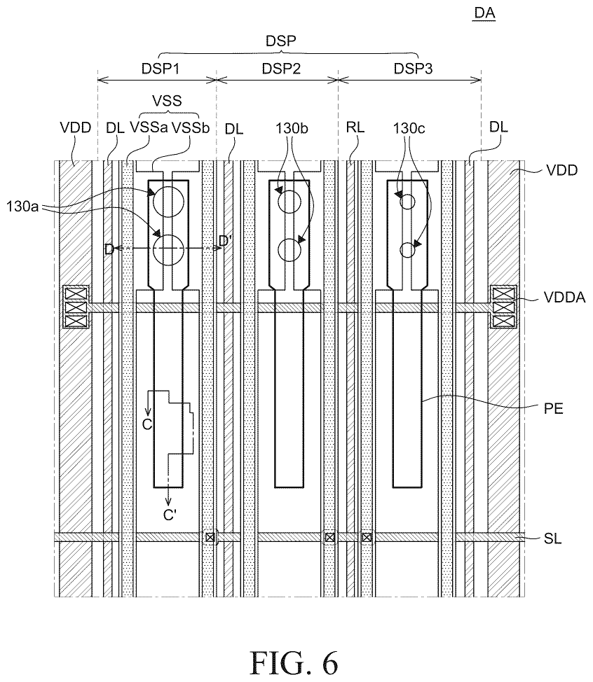

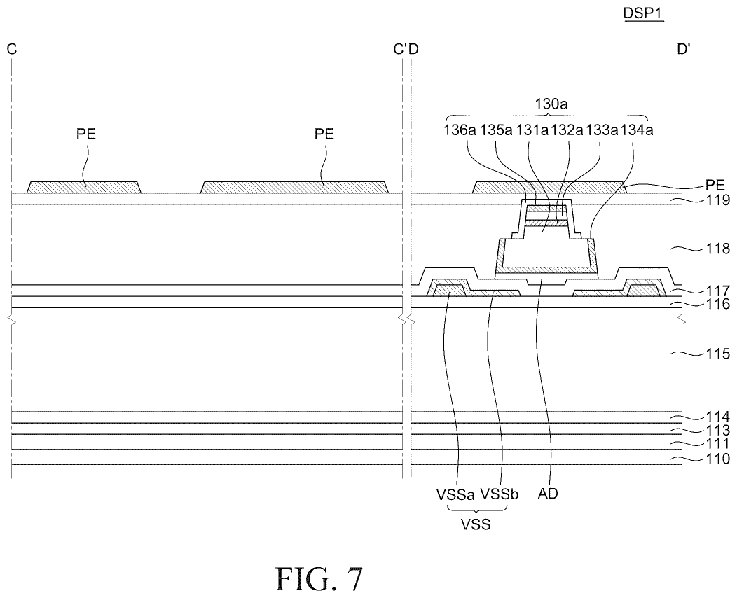

First, the dummy area DA of the non-display area NA is disposed to surround the display area AA. The dummy area DA is an area for uniformly forming electric fields throughout an entirety of the display area AA in a process of assembling the plurality of sub-pixels SP in the display area AA. The dummy area DA includes a plurality of dummy sub-pixels DSP, and at least low potential power supply lines VSS can be formed in the dummy sub-pixels DSP. The plurality of light emitting elements 130 can be transferred to the dummy sub-pixels DSP, similarly to the case of the sub-pixels SP, but a pixel circuit is not disposed in the dummy sub-pixels DSP, and thus, the plurality of light emitting elements 130 transferred cannot emit light in the dummy sub-pixels DSP. A more detailed description of the dummy area DA will be described later with reference to FIGS. 6 and 7.

The gate driving area GA of the non-display area NA is an area in which the gate driver GD is mounted. The gate driving area GA can be disposed in portions of the non-display area NA on both sides of the display area AA. The gate driving area GA can be disposed outside the dummy area DA. A logic unit, a gate power supply unit, a clock unit, and the like constituting the gate driver GD, can be disposed in the gate driving area GA. Meanwhile, although the gate driving area GA is illustrated as being disposed on both sides of the display area AA in FIG. 3, the gate driving area GA can be disposed on only one side of the display area AA, embodiments of the present disclosure are not limited thereto.

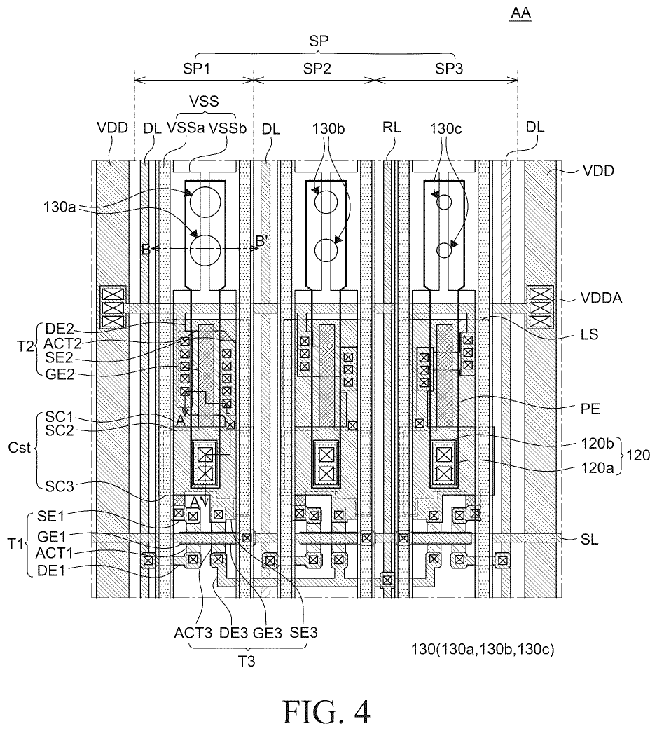

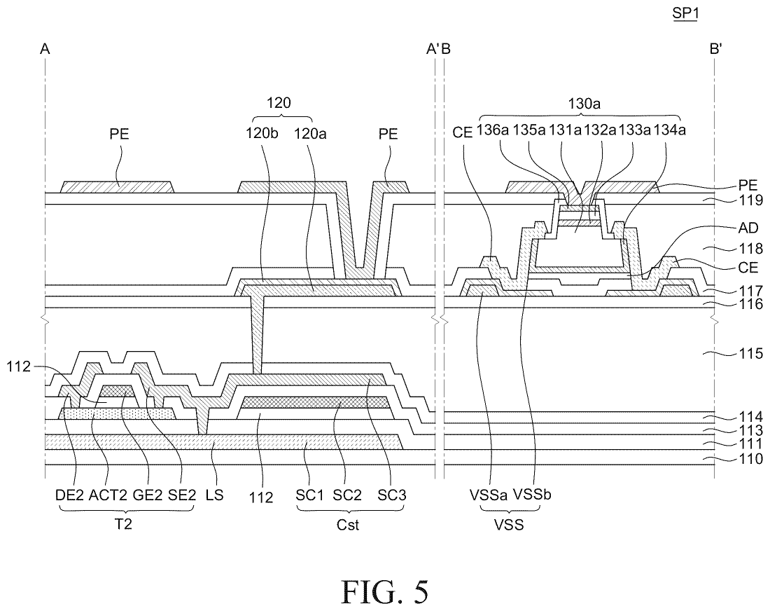

Hereinafter, the plurality of sub-pixels SP of the display area AA will be described in detail with reference to FIGS. 4 and 5.

FIG. 4 is an enlarged plan view of a display area of the display device according to an exemplary embodiment of the present disclosure. FIG. 5 is a cross-sectional view taken along line A-A′ and line B-B′ of FIG. 4. In FIG. 4, hatchings of a cladding layer VSSb, pixel electrodes PE, and the light emitting elements 130 are omitted, and illustration of contact electrodes CE is omitted for convenience of description.

Referring to FIGS. 4 and 5, each of the plurality of sub-pixels SP includes a first transistor T1, a second transistor T2, a third transistor T3, a storage capacitor Cst, and one or more light emitting elements 130 (e.g., 130a, 130b, 130c).

Further, the plurality of sub-pixels SP can be connected to the plurality of scan lines SL, the plurality of data lines DL, a plurality of reference lines RL, a plurality of high potential power supply lines VDD, and a plurality of low potential power supply lines VSS.

The plurality of sub-pixels SP includes a first sub-pixel SP1, a second sub-pixel SP2, and a third sub-pixel SP3. Each of the first sub-pixel SP1, the second sub-pixel SP2, and the third sub-pixel SP3 includes the light emitting element 130 and a pixel circuit to independently emit light. For example, the first sub-pixel SP1 can be a red sub-pixel, the second sub-pixel SP2 can be a green sub-pixel, and the third sub-pixel SP3 can be a blue sub-pixel, but embodiments of the present disclosure are not limited thereto, for example, the plurality of sub-pixels SP can further include white sub-pixel.

Referring to FIG. 5, the substrate 110 is a component to support various components included in the display device 100 and can be formed of an insulating material. For example, the substrate 110 can be formed of glass, resin or the like. In addition, the substrate 110 can be formed to include a polymer or plastic, or can be formed of a material having flexibility, but materials of the substrate according to embodiments of the present disclosure are not limited thereto.

The high potential power supply lines VDD, the plurality of data lines DL, the reference lines RL, a light blocking layer LS, and a first capacitor electrode SC1 are disposed on the substrate 110.

The high potential power supply line VDD is a line that transmits a high potential power supply voltage to each of the plurality of sub-pixels SP. The plurality of high potential power supply lines VDD can transmit high potential power supply voltages to the second transistors T2 of the plurality of respective sub-pixels SP. The second transistor T2 can be a driving transistor for controlling driving current. The high potential power supply line VDD can extend in a column direction between the plurality of sub-pixels SP. For example, the high potential power supply line VDD can be disposed in the column direction between the first sub-pixel SP1 and the third sub-pixel SP3. Alternatively, the high potential power supply line VDD can also be disposed in the column direction between other sub-pixels. In addition, the high potential power supply line VDD can transmit a high potential power supply voltage to each of the plurality of sub-pixels SP disposed in a row direction through an auxiliary high potential power supply line VDDA, which will be described later. But embodiments of the present disclosure are not limited thereto. Further, the column direction and the row direction according to the embodiments of the present disclosure are relative, and the column direction and the row direction are interchangeable.

The plurality of data lines DL are lines that transfer data voltages to each of the plurality of sub-pixels SP. The plurality of data lines DL can be connected to the first transistors T1 of the plurality of respective sub-pixels SP. The first transistor T1 can be a switching transistor. The plurality of data lines DL can extend in the column direction between the plurality of sub-pixels SP. For example, the data line DL extending in the column direction between the first sub-pixel SP1 and the high potential power supply line VDD can transfer a data voltage to the first sub-pixel SP1, the data line DL disposed between SP1 and the second sub-pixel SP2 can transfer a data voltage to the second sub-pixel SP2, and the data line DL disposed between the third sub-pixel SP3 and the high potential power supply line VDD can transfer a data voltage to the third sub-pixel SP3. But embodiments of the present disclosure are not limited thereto.

The reference line RL is a line that transmits a reference voltage to each of the plurality of sub-pixels SP. The reference lines RL can be connected to the third transistors T3 of the plurality of respective sub-pixels SP. The third transistor T3 can be a sensing transistor that senses characteristics of the second transistor T2. The reference line RL can extend in the column direction between the plurality of sub-pixels SP. For example, the reference line RL can extend in the column direction between the second sub-pixel SP2 and the third sub-pixel SP3. A third drain electrode DE3 of the third transistor T3 of each of the first sub-pixel SP1, the second sub-pixel SP2, and the third sub-pixel SP3 adjacent to the reference lines RL can extend in the row direction and be electrically connected to the reference line RL. But embodiments of the present disclosure are not limited thereto.

The light blocking layer LS is disposed on the substrate 110 in each of the plurality of sub-pixels SP. The light blocking layer LS can block light incident on the transistor from a lower portion of the substrate 110 to reduce or minimize leakage current. For example, the light blocking layer LS can block light incident on a second active layer ACT2 of the second transistor T2 that is a driving transistor. But embodiments of the present disclosure are not limited thereto.

The first capacitor electrode SC1 is disposed on the substrate 110 in each of the plurality of sub-pixels SP. The first capacitor electrode SC1, together with other capacitor electrodes SC2 and SC3, can form the storage capacitor Cst. The first capacitor electrode SC1 can be integrally formed with the light blocking layer LS. But embodiments of the present disclosure are not limited thereto.

A buffer layer 111 is disposed on the high potential power supply lines VDD, the plurality of data lines DL, the reference lines RL, the light blocking layer LS, and the first capacitor electrodes SC1. The buffer layer 111 can reduce or minimize penetration of moisture or impurities through the substrate 110. The buffer layer 111 can be composed of, for example, a single layer or multiple layers of silicon oxide (SiOx) or silicon nitride (SiNx), but embodiments of the present disclosure are not limited thereto. However, the buffer layer 111 can be omitted depending on the type of the substrate 110 or the type of a transistor, but embodiments of the present disclosure are not limited thereto.

First, the first transistor T1 is disposed on the buffer layer 111 in each of the plurality of sub-pixels SP. The first transistor T1 transfers a data voltage to a second gate electrode GE2 of the second transistor T2. The first transistor T1 can be turned on by a scan signal from the scan line SL, and the data voltage from the data line DL can be transmitted to the second gate electrode GE2 of the second transistor T2 through the turned on first transistor T1. Accordingly, the first transistor T1 can be referred to as a switching transistor.

The first transistor T1 includes a first active layer ACT1, a first gate electrode GE1, a first source electrode SE1, and a first drain electrode DE1.

The first active layer ACT1 is disposed on the buffer layer 111. The first active layer ACT1 can be formed of a semiconductor material such as an oxide semiconductor, amorphous silicon, or polysilicon, but embodiments of the present disclosure are not limited thereto.

A gate insulating layer 112 is disposed on the first active layer ACT1. The gate insulating layer 112 is an insulating layer for insulating the first active layer ACT1 and the first gate electrode GE1, and can be composed of a single layer or multiple layers of silicon oxide (SiOx) or silicon nitride (SiNx). However, embodiments of the present disclosure are not limited thereto.

The first gate electrode GE1 is disposed on the gate insulating layer 112. The first gate electrode GE1 can be electrically connected to the scan line SL. The first gate electrode GE1 can be formed of a conductive material such as copper (Cu), aluminum (Al), molybdenum (Mo), nickel (Ni), titanium (Ti), chromium (Cr), or an alloy thereof, but embodiments of the present disclosure not limited thereto.

The interlayer insulating layer 113 is disposed on the first gate electrode GE1. Contact holes for connecting each of the first source electrode SE1 and the first drain electrode DE1 to the first active layer ACT1 are formed in the interlayer insulating layer 113. The interlayer insulating layer 113 is an insulating layer for protecting components under the interlayer insulating layer 113, and can be composed of a single layer or multiple layers of silicon oxide (SiOx) or silicon nitride (SiNx), but embodiments of the present disclosure are not limited thereto.

The first source electrode SE1 and the first drain electrode DE1 electrically connected to the first active layer ACT1 are disposed on the interlayer insulating layer 113. The first drain electrode DE1 can be connected to the data line DL and the first active layer ACT1, and the first source electrode SE1 can be connected to the first active layer ACT1 and the second gate electrode GE2 of the second transistor T2. The first source electrode SE1 and the first drain electrode DE1 can be formed of a conductive material, for example, copper (Cu), aluminum (Al), molybdenum (Mo), nickel (Ni), titanium (Ti), chromium (Cr) or an alloy thereof, but embodiments of the present disclosure are not limited thereto.

The second transistor T2 is disposed on the buffer layer 111 in each of the plurality of sub-pixels SP. The second transistor T2 is a transistor that supplies a driving current to the light emitting element 130. The second transistor T2 can be turned on to control a driving current flowing to the light emitting element 130. Accordingly, the second transistor T2 for controlling the driving current can be referred to as a driving transistor.

The second transistor T2 includes the second active layer ACT2, the second gate electrode GE2, a second source electrode SE2, and a second drain electrode DE2.

The second active layer ACT2 is disposed on the buffer layer 111. The second active layer ACT2 can be formed of a semiconductor material such as an oxide semiconductor, amorphous silicon, or polysilicon, but embodiments of the present disclosure are not limited thereto.

The gate insulating layer 112 is disposed on the second active layer ACT2, and the second gate electrode GE2 is disposed on the gate insulating layer 112. The second gate electrode GE2 can be electrically connected to the first source electrode SE1 of the first transistor T1. The second gate electrode GE2 can be formed of a conductive material such as copper (Cu), aluminum (Al), molybdenum (Mo), nickel (Ni), titanium (Ti), chromium (Cr), or an alloy thereof, but embodiments of the present disclosure are not limited thereto.

The interlayer insulating layer 113 is disposed on the second gate electrode GE2, and the second source electrode SE2 and the second drain electrode DE2 electrically connected to the second active layer ACT2 are disposed on the interlayer insulating layer 113. The second drain electrode DE2 can be electrically connected to the second active layer ACT2 and the high potential power supply line VDD, and the second source electrode SE2 can be connected to the second active layer ACT2 and the light emitting element 130. The second source electrode SE2 and the second drain electrode DE2 can be formed of a conductive material, for example, copper (Cu), aluminum (Al), molybdenum (Mo), nickel (Ni), titanium (Ti), chromium (Cr) or an alloy thereof, but embodiments of the present disclosure are not limited thereto.

The third transistor T3 is disposed on the buffer layer 111 in each of the plurality of sub-pixels SP. The third transistor T3 is a transistor for compensating a threshold voltage of the second transistor T2. The third transistor T3 is connected between the second source electrode SE2 of the second transistor T2 and the reference line RL. The third transistor T3 can be turned on and transfer a reference voltage to the second source electrode SE2 of the second transistor T2 to sense the threshold voltage of the second transistor T2. Accordingly, the third transistor T3 that senses characteristics of the second transistor T2 can be referred to as a sensing transistor.

The third transistor T3 includes a third active layer ACT3, a third gate electrode GE3, a third source electrode SE3, and the third drain electrode DE3.

The third active layer ACT3 is disposed on the buffer layer 111. The third active layer ACT3 can be formed of a semiconductor material such as an oxide semiconductor, amorphous silicon, or polysilicon, but embodiments of the present disclosure are not limited thereto.

The gate insulating layer 112 is disposed on the third active layer ACT3, and the third gate electrode GE3 is disposed on the gate insulating layer 112. The third gate electrode GE3 can be electrically connected to the scan line SL. The third gate electrode GE3 can be formed of a conductive material such as copper (Cu), aluminum (Al), molybdenum (Mo), nickel (Ni), titanium (Ti), chromium (Cr), or an alloy thereof, but embodiments of the present disclosure are not limited thereto.

The interlayer insulating layer 113 is disposed on the third gate electrode GE3, and the third source electrode SE3 and the third drain electrode DE3 electrically connected to the third active layer ACT3 are disposed on the interlayer insulating layer 113. The third drain electrode DE3 can be electrically connected to the third active layer ACT3 and the reference line RL, and the third source electrode SE3 can be electrically connected to the third active layer ACT3 and the second source electrode SE2 of the second transistor T2. The third source electrode SE3 and the third drain electrode DE3 can be formed of a conductive material, for example, copper (Cu), aluminum (Al), molybdenum (Mo), nickel (Ni), titanium (Ti), chromium (Cr) or an alloy thereof, but embodiments of the present disclosure are not limited thereto.

Next, a second capacitor electrode SC2 is disposed on the gate insulating layer 112. The second capacitor electrode SC2 is one of electrodes forming the storage capacitor Cst and can be disposed to overlap the first capacitor electrode SCL. The second capacitor electrode SC2 is integrally formed with the second gate electrode GE2 of the second transistor T2 and can be electrically connected to the second gate electrode GE2. The first capacitor electrode SC1 and the second capacitor electrode SC2 can be spaced apart from each other with the buffer layer 111 and the gate insulating layer 112 interposed therebetween.

In addition, the plurality of scan lines SL, the auxiliary high potential power supply line VDDA, and a third capacitor electrode SC3 are disposed on the interlayer insulating layer 113.

First, the scan line SL is a line that transmits a scan signal to each of the plurality of sub-pixels SP. The scan line SL can cross the plurality of sub-pixels SP and extend in the row direction. The scan line SL can be electrically connected to the first gate electrode GE1 of the first transistor T1 and the third gate electrode GE3 of the third transistor T3 of each of the plurality of sub-pixels SP.

The auxiliary high potential power supply line VDDA is disposed on the interlayer insulating layer 113. The auxiliary high potential power supply line VDDA can extend in the row direction and can be disposed across the plurality of sub-pixels SP. The auxiliary high potential power supply line VDDA can be electrically connected to the high potential power supply lines VDD extending in the column direction and the second drain electrodes DE2 of the second transistors T2 of the plurality of respective sub-pixels SP disposed in the row direction.

The third capacitor electrode SC3 is disposed on the interlayer insulating layer 113. The third capacitor electrode SC3 is an electrode forming the storage capacitor Cst, and can be disposed to overlap the first capacitor electrode SC1 and the second capacitor electrode SC2.

The third capacitor electrode SC3 can be integrally formed with the second source electrode SE2 of the second transistor T2 and electrically connected to the second source electrode SE2. Further, the second source electrode SE2 and the first capacitor electrode SC1 can also be electrically connected through a contact hole formed in multi layers therebetween. For example, the second source electrode SE2 can be electrically connected to the first capacitor electrode SC1 through a contact hole formed in the interlayer insulating layer 113 and the buffer layer 111. Accordingly, the first capacitor electrode SC1 and the third capacitor electrode SC3 can be electrically connected to the second source electrode SE2 of the second transistor T2.

The storage capacitor Cst can store a potential difference between the second gate electrode GE2 and the second source electrode SE2 of the second transistor T2 while the light emitting element 130 emits light, so that a constant current is supplied to the light emitting element 130. The storage capacitor Cst includes the first capacitor electrode SC1 formed on the substrate 110 and connected to the second source electrode SE2, the second capacitor electrode SC2 formed on the buffer layer 111 and the gate insulating layer 112 and connected to the second gate electrode GE2, and the third capacitor electrode SC3 formed on the interlayer insulating layer 113 and connected to the second source electrode SE2, so that the storage capacitor Cst can store a voltage between the second gate electrode GE2 and the second source electrode SE2 of the second transistor T2.

A first passivation layer 114 is disposed on the first transistor T1, the second transistor T2, the third transistor T3, and the storage capacitor Cst. The first passivation layer 114 is an insulating layer for protecting components under the first passivation layer 114, and can be composed of a single layer or multiple layers of silicon oxide (SiOx) or silicon nitride (SiNx), but embodiments of the present disclosure are limited thereto.

A first planarization layer 115 is disposed on the first passivation layer 114. The first planarization layer 115 can planarize an upper portion of the substrate 110 on which the plurality of transistors and the storage capacitor Cst are disposed. The first planarization layer 115 can be composed of a single layer or multiple layers, and can be formed of, for example, photoresist or an acryl-based organic material, but embodiments of the present disclosure are not limited thereto.

A second passivation layer 116 is disposed on the first planarization layer 115. The second passivation layer 116 is an insulating layer for protecting components under the second passivation layer 116, and can be composed of a single layer or multiple layers of silicon oxide (SiOx) or silicon nitride (SiNx), but embodiments of the present disclosure are limited thereto.

Connection electrodes 120 and the plurality of low potential power supply lines VSS are disposed on the second passivation layer 116.

First, the connection electrode 120 is disposed in each of the plurality of sub-pixels SP. The connection electrode 120 is an electrode that electrically connects the second transistor T2 and the pixel electrode PE. The connection electrode 120, and the second source electrode SE2 and the third capacitor electrode SC3 can be electrically connected through a contact hole formed in multi layers therebetween. For example, the connection electrode 120 can be electrically connected to the second source electrode SE2 and the third capacitor electrode SC3 through a contact hole formed in the second passivation layer 116, the first planarization layer 115, and the first passivation layer 114. But embodiments of the present disclosure are limited thereto.

The connection electrode 120 can have a multilayer structure including a first connection layer 120a and a second connection layer 120b. The first connection layer 120a is disposed on the second passivation layer 116, and the second connection layer 120b covering the first connection layer 120a is disposed. The second connection layer 120b can be disposed to surround both an upper surface and a side surface of the first connection layer 120a. The second connection layer 120b is formed of a material that is more resistant to corrosion compared to the first connection layer 120a, and thus, can reduce or minimize a short circuit defect due to migration between the first connection layer 120a and adjacent lines when the display device 100 is manufactured. For example, the first connection layer 120a can be formed of a conductive material such as copper (Cu) or chromium (Cr), and the second connection layer 120b can be formed of molybdenum (Mo) or molybdenum titanium (MoTi), but embodiments of the present disclosure are not limited thereto, for example, the second connection layer 120b can be disposed to cover an upper surface of the first connection layer 120a only.

The plurality of low potential power supply lines VSS are disposed on the second passivation layer 116. The plurality of low potential power supply lines VSS are lines that transmit low potential power supply voltages to the light emitting elements 130. The plurality of low potential power supply lines VSS can extend in the column direction in each of the plurality of sub-pixels SP. For example, a pair of low potential power supply lines VSS spaced apart from each other at a predetermined interval can be disposed in each of the first sub-pixel SP1, the second sub-pixel SP2, and the third sub-pixel SP3, but embodiments of the present disclosure are not limited thereto.

Each of the plurality of low potential power supply lines VSS includes a conductive layer VSSa and a cladding layer VSSb. The conductive layer VSSa is disposed on the second passivation layer 116, and the cladding layer VSSb covering both an upper surface and a side surface of the conductive layer VSSa is disposed on the conductive layer VSSa. For example, the conductive layer VSSa can be formed of a conductive material such as copper (Cu) or chromium (Cr). Further, the cladding layer VSSb can be formed of a material that is more resistant to corrosion compared to the conductive layer VSSa, such as molybdenum (Mo) or molybdenum titanium (MoTi), but embodiments of the present disclosure are not limited thereto.

A third passivation layer 117 is disposed on the connection electrode 120 and the low potential power supply line VSS. The third passivation layer 117 is an insulating layer for protecting components under the third passivation layer 117, and can be composed of a single layer or multiple layers of silicon oxide (SiOx) or silicon nitride (SiNx), but embodiments of the present disclosure are limited thereto.

Next, the plurality of light emitting elements 130 are disposed on the third passivation layer 117. One or more light emitting elements 130 are disposed in one sub-pixel SP. The light emitting element 130 is an element that emits light by current. The light emitting elements 130 can include light emitting elements 130 that emit red light, green light, blue light, and the like, and through a combination thereof, can implement light of various colors including white. In addition, light of various colors can be implemented by using the light emitting element 130 that emits light of a specific color and a light conversion member that converts light from the light emitting element 130 into light of a different color. The light emitting element 130 is electrically connected between the second transistor T2 and the low potential power supply line VSS, and can receive a driving current from the second transistor T2 to emit light.

In this case, the plurality of light emitting elements 130 disposed in one sub-pixel SP can be connected in parallel. For example, one electrode of each of the plurality of light emitting elements 130 can be connected to the source electrode of the same second transistor T2, and the other electrode thereof can be connected to the same low potential power supply line VSS.

Meanwhile, the light emitting elements 130 can include first light emitting elements 130a, second light emitting elements 130b, and third light emitting elements 130c. The first light emitting element 130a can be disposed in the first sub-pixel SP1 among the plurality of sub-pixels SP, the second light emitting element 130b can be disposed in the second sub-pixel SP2 among the plurality of sub-pixels SP, and the third light emitting element 130c can be disposed in the third sub-pixel SP3 among the plurality of sub-pixels SP. The first light emitting element 130a, the second light emitting element 130b, and the third light emitting element 130c can emit light of different colors, for example, the first light emitting element 130a can be a red light emitting element, the second light emitting element 130b can be a green light emitting element 130, and the third light emitting element 130c can be a blue light emitting element 130, but embodiments of the present disclosure are not limited thereto.

In this case, the light emitting elements 130 disposed in each of the plurality of sub-pixels SP can have different sizes. For example, the first light emitting element 130a can have a largest size, the third light emitting element 130c can have a smallest size, and the second light emitting element 130b can have a size between those of the first light emitting element 130a and the third light emitting element 130c. Each of the first light emitting element 130a, the second light emitting element 130b, and the third light emitting element 130c can have different sizes or luminous efficiencies, so that designs of the second transistors T2 for driving the first light emitting element 130a, the second light emitting element 130b, and the third light emitting element 130c can also be varied. For example, the second transistor T2 of the first sub-pixel SP1 for driving the first light emitting element 130a includes the second active layer ACT2 having a largest size, and the second transistor T2 of the third sub-pixel SP3 can include the second active layer ACT2 having a smallest size. However, the sizes of the light emitting elements 130 are exemplary, and the sizes of the light emitting elements 130 can be all the same or can be formed in different sizes, but embodiments of the present disclosure are not limited thereto.

In addition, FIG. 4 illustrates that two light emitting elements 130 are disposed in each of the plurality of sub-pixels SP for convenience of description, for example, two first light emitting elements 130a are disposed in the first sub-pixel SP1, two second light emitting elements 130b are disposed in the second sub-pixel SP2, and two third light emitting elements 130c are disposed in the third sub-pixel SP3. However, the number of light emitting elements 130 disposed in each of the plurality of sub-pixels SP is not limited thereto and other variations are possible.

Referring to FIG. 5, the first light emitting element 130a includes a first semiconductor layer 131a, a light emitting layer 132a, a second semiconductor layer 133a, a first electrode 134a, a second electrode 135a, and an encapsulation layer 136a.

The first semiconductor layer 131a is disposed on the third passivation layer 117, and the second semiconductor layer 133a is disposed on the first semiconductor layer 131a. The first semiconductor layer 131a and the second semiconductor layer 133a can be layers formed by doping a specific material with n-type impurities and p-type impurities. For example, each of the first semiconductor layer 131a and the second semiconductor layer 133a can be layers formed by doping materials such as gallium nitride (GaN), indium aluminum phosphide (InAlP), gallium arsenide (GaAs), and the like, with n-type impurities and p-type impurities. In addition, the p-type impurity can be magnesium (Mg), zinc (Zn), beryllium (Be) or the like, and the n-type impurity can be silicon (Si), germanium (Ge), tin (Sn) or the like, but embodiments of the present disclosure are not limited thereto.

A portion of the first semiconductor layer 131a can protrude outside the second semiconductor layer 133a. An upper surface of the first semiconductor layer 131a can include a portion overlapping a lower surface of the second semiconductor layer 133a and a portion disposed outside the lower surface of the second semiconductor layer 133a. However, sizes and shapes of the first semiconductor layer 131a and the second semiconductor layer 133a can be variously modified, but are not limited thereto.

The light emitting layer 132a is disposed between the first semiconductor layer 131a and the second semiconductor layer 133a. The light emitting layer 132a can receive holes and electrons from the first semiconductor layer 131a and the second semiconductor layer 133a to emit light. The light emitting layer 132a can be formed of a single or multi-quantum well (MQW) structure, and can be formed of, for example, indium gallium nitride (InGaN) or gallium nitride (GaN), but embodiments of the present disclosure are not limited thereto.

The first electrode 134a is disposed to surround a lower surface and a side surface of the first semiconductor layer 131a. The first electrode 134a is an electrode for electrically connecting the first light emitting element 130a and the low potential power supply line VSS. The first electrode 134a can be formed of a conductive material, for example, a transparent conductive material such as indium tin oxide (ITO) or indium zinc oxide (IZO), or an opaque conductive material such as titanium (Ti), gold (Au), silver (Ag), copper (Cu), or an alloy thereof, but embodiments of the present disclosure are not limited thereto.

The second electrode 135a is disposed on an upper surface of the second semiconductor layer 133a. The second electrode 135a is an electrode that electrically connects the pixel electrode PE, which will be described later, and the second semiconductor layer 133a. The second electrode 135a can be formed of a conductive material, for example, a transparent conductive material such as indium tin oxide (ITO) or indium zinc oxide (IZO), but embodiments of the present disclosure are not limited thereto.

The encapsulation layer 136a surrounding at least a portion of the first semiconductor layer 131a, the light emitting layer 132a, the second semiconductor layer 133a, the first electrode 134a, and the second electrode 135a is disposed. The encapsulation layer 136a is formed of an insulating material and can protect the first semiconductor layer 131a, the light emitting layer 132a, and the second semiconductor layer 133a. The encapsulation layer 136a can be disposed to cover the light emitting layer 132a, a portion of the side surface of the first semiconductor layer 131a adjacent to the light emitting layer 132a, and a portion of a side surface of the second semiconductor layer 133a adjacent to the light emitting layer 132a. The first electrode 134a and the second electrode 135a can be exposed from the encapsulation layer 136a, and electrically connect the contact electrode CE and the pixel electrode PE, which will be formed later, and the first electrode 134a and the second electrode 135a.

Meanwhile, among the plurality of light emitting elements 130, the second light emitting element 130b and the third light emitting element 130c can have the same or basically the same structure as or can have a different structure from that of the first light emitting element 130a illustrated in FIG. 5. For example, the second light emitting element 130b and the third light emitting element 130c can have the same or basically the same structure as the first light emitting element 130a by including a first semiconductor layer, a light emitting layer, a second semiconductor layer, a first electrode, a second electrode, and an encapsulation layer, in the same manner as the first light emitting element 130a. In addition, when the second light emitting element 130b and the third light emitting element 130c have structures different from that of the first light emitting element 130a, the second light emitting element 130b and the third light emitting element 130c can have a structure in which the first electrode is disposed only on the lower surface of the first semiconductor layer, compared to the first light emitting element 130a. However, structures of the first light emitting element 130a, the second light emitting element 130b, and the third light emitting element 130c are exemplary, and the first light emitting element 130a, the second light emitting element 130b, and the third light emitting element 130c can be designed in various structures, as long as they are light emitting diodes (LED) or micro-light emitting diodes (micro-LEDs).

Next, an adhesive layer AD is disposed between the plurality of light emitting elements 130 and the third passivation layer 117. The adhesive layer AD can be an organic film temporarily fixing the light emitting elements 130 during self-assembling of the light emitting elements 130. In manufacturing the display device 100, when an organic film covering the light emitting element 130 is formed, a portion of the organic film can fill a space between the light emitting element 130 and the third passivation layer 117 to temporarily fix the light emitting element 130 on the third passivation layer 117. Thereafter, even if the organic film is removed, a portion of the organic film permeated under the light emitting element 130 can remain without being removed and become the adhesive layer AD. The adhesive layer AD can be formed of an organic material such as photoresist or an acryl-based organic material, but embodiments of the present disclosure are not limited thereto.

The contact electrode CE is disposed on a side surface of the light emitting element 130. The contact electrode CE is an electrode for electrically connecting the light emitting element 130 and the low potential power supply line VSS. The contact electrode CE can be electrically connected to the low potential power supply line VSS through a contact hole formed in the third passivation layer 117. Further, the contact electrode CE is disposed to surround at least a portion of the first semiconductor layer 131a and the first electrode 134a of the light emitting element 130, and can electrically connect the first semiconductor layer 131a and the first electrode 134a, and the low potential power supply line VSS.

Next, a second planarization layer 118 is disposed on the light emitting element 130 and the contact electrode CE. The second planarization layer 118 can planarize an upper portion of the substrate 110 on which the light emitting element 130 is disposed, and can fix the light emitting element 130 onto the substrate 110, together with the adhesive layer AD. The second planarization layer 118 can be composed of a single layer or multiple layers, and can be formed of, for example, photoresist or an acryl-based organic material, but embodiments of the present disclosure are not limited thereto.

A fourth passivation layer 119 is disposed on the second planarization layer 118. The fourth passivation layer 119 is an insulating layer for protecting components under the fourth passivation layer 119, and can be composed of a single layer or multiple layers of silicon oxide (SiOx) or silicon nitride (SiNx), but embodiments of the present disclosure are limited thereto. The fourth passivation layer 119 can be disposed to cover an upper edge portion of the light emitting element 130 that is exposed from the second planarization layer 118 and an inner surface of a contact hole of the second planarization layer 118 to which the connection electrode 120 is exposed. The second planarization layer 118 is formed to have a thickness greater than that of the plurality of light emitting elements 130 and can allow an upper portion of the light emitting element 130 to be exposed from the second planarization layer 118 through an ashing process that reduces an overall thickness of the second planarization layer 118. In this case, during the ashing process of the second planarization layer 118, the side surface and the like of the light emitting element 130 can be exposed, and disconnection or a short circuit of the pixel electrode PE can be caused due to a gap between the light emitting element 130 and the second planarization layer 118. Accordingly, to fill the gap and protect the light emitting element 130, an additional fourth passivation layer 119 can be further formed on the second planarization layer 118 and the light emitting element 130. However, the fourth passivation layer 119 can be omitted according to design, but embodiments of the present disclosure are not limited thereto.

The pixel electrodes PE are disposed on the fourth passivation layer 119. The pixel electrode PE is an electrode for electrically connecting the plurality of light emitting elements 130 and the connection electrode 120. The pixel electrode PE can be electrically connected to the light emitting element 130, the connection electrode 120, and the second transistor T2 through the contact hole formed in the second planarization layer 118. Accordingly, the second electrode 135a of the light emitting element 130, the connection electrode 120, and the second source electrode SE2 of the second transistor T2 can be electrically connected to one another through the pixel electrode PE. The pixel electrode PE can be formed of a conductive material, for example, a transparent conductive material such as indium tin oxide (ITO) or indium zinc oxide (IZO), but embodiments of the present disclosure are not limited thereto.

Hereinafter, the dummy area DA will be described in detail with reference to FIGS. 6 and 7.

FIG. 6 is an enlarged plan view of a dummy area of the display device according to an exemplary embodiment of the present disclosure. FIG. 7 is a cross-sectional view taken along line C-C′ and line D-D′ of FIG. 6. Referring to FIGS. 6 and 7, the dummy area DA includes the plurality of dummy sub-pixels DSP. The plurality of dummy sub-pixels DSP includes a first dummy sub-pixel DSP1, a second dummy sub-pixel DSP2, and a third dummy sub-pixel DSP3. The first light emitting elements 130a can be disposed equally in the first dummy sub-pixel DSP1 and the first sub-pixel SP1, the second light emitting elements 130b can be disposed equally in the second dummy sub-pixel DSP2 and the second sub-pixel SP2, and the third light emitting elements 130c can be disposed equally in the third dummy sub-pixel DSP3 and the third sub-pixel SP3. Although only one first light emitting elements 130a is shown in first dummy sub-pixel DSP1 of FIG. 7, embodiments of the present disclosure are not limited thereto. For example, the first dummy sub-pixel DSP1 can include two first light emitting elements 130a, the second dummy sub-pixel DSP2 can include two second light emitting elements 130b, and the third dummy sub-pixel DSP3 can include two third light emitting elements 130c. The plurality of dummy sub-pixels DSP includes the plurality of light emitting elements 130 and a plurality of the pixel electrodes PE. However, the plurality of dummy sub-pixels DSP do not include the pixel circuit including the first transistor T1, the second transistor T2, the third transistor T3, and the storage capacitor Cst. Accordingly, even if the light emitting element 130 is disposed in the dummy sub-pixel DSP, the light emitting element 130 in the dummy area DA cannot emit light because there is no pixel circuit for driving the light emitting element 130.

In addition, in the dummy area DA, a plurality of lines, for example, a plurality of scan lines SL, a plurality of data lines DL, a plurality of reference lines RL, a plurality of high potential power supply lines VDD, and a plurality of low potential power supply lines VSS can be disposed. The plurality of lines disposed in the dummy area DA are substantially the same as the plurality of lines disposed in the display area AA, and accordingly, both of them are integrally formed. For example, each of the plurality of data lines DL, the plurality of reference lines RL, the plurality of high potential power supply lines VDD, and the plurality of low potential power supply lines VSS can be disposed across an entirety of the dummy area DA and the display area AA.

Referring to FIG. 7, the buffer layer 111, the interlayer insulating layer 113, the first passivation layer 114, the first planarization layer 115, and the second passivation layer 116 are sequentially formed on the substrate 110 in the dummy area DA.

The plurality of low potential power supply lines VSS are disposed on the second passivation layer 116. The plurality of low potential power supply lines VSS can extend in a column direction from each of the plurality of dummy sub-pixels DSP. Accordingly, a pair of low potential power supply lines VSS spaced apart from each other at a predetermined interval can be disposed equally in each of the plurality of sub-pixels SP and the plurality of dummy sub-pixels DSP.

The third passivation layer 117 is disposed on the plurality of low potential power supply lines VSS. In this case, in the third passivation layer 117 disposed in the dummy sub-pixel DSP, a contact hole through which the low potential power supply line VSS is exposed may not be formed, and the light emitting element 130 and the low potential power supply line VSS can be insulated from each other. However, a contact hole exposing the low potential power supply line VSS can be formed in the third passivation layer 117, and even if the contact hole is formed, no transistor or the like is formed in the dummy sub-pixel DSP, so that driving of the light emitting element 130 can be prevented.

The plurality of light emitting elements 130 are disposed on the third passivation layer 117. A plurality of the first light emitting elements 130a can be disposed in the first dummy sub-pixel DSP1, a plurality of the second light emitting elements 130b are disposed in the second dummy sub-pixel DSP2, and a plurality of the third light emitting elements 130c can be disposed in the third dummy sub-pixel DSP3.

The second planarization layer 118 and the fourth passivation layer 119 are disposed on the plurality of light emitting elements 130 in the dummy area DA. The second planarization layer 118 and the fourth passivation layer 119 disposed in the dummy area DA may not include a separate contact hole and cover the upper portion of the light emitting element 130. Accordingly, in the display area AA, the upper portion of the light emitting element 130 is exposed from the second planarization layer 118 and the fourth passivation layer 119 and connected to the pixel electrode PE. However, in the dummy area DA, the second planarization layer 118 and the fourth passivation layer 119 cover all of the light emitting elements 130, so that the light emitting element 130 may not be connected to the pixel electrode PE.

The pixel electrodes PE are disposed on the fourth passivation layer 119 The pixel electrode PE of the dummy area DA can be formed of the same or basically the same material through the same process as the pixel electrode PE of the display area AA. In this case, since a contact hole through which the light emitting element 130 or the like is exposed is not formed in the fourth passivation layer 119 and the second planarization layer 118 disposed in the dummy area DA, the pixel electrode PE can be disposed on the fourth planarization layer in a state in which it is floating.

In this case, uniformity of the pixel electrode PE can be improved by forming the pixel electrode PE not only in the display area AA but also in the dummy area DA. Specifically, when forming the pixel electrodes PE using a mask, the pixel electrodes PE can be formed to have slightly non-uniform thicknesses or sizes in an outer portion of the mask according to sagging or the like of the mask. Accordingly, by forming the mask such that the outer portion of the mask does not correspond to the display area AA but corresponds to the dummy area DA outside the display area AA, the pixel electrodes PE of uniform quality throughout the entirety of the display area AA can be formed.

Meanwhile, although FIG. 7 illustrates that no contact electrode is formed, the contact electrode CE can be formed in the dummy area DA in the same manner as the pixel electrode PE, but embodiments of the present disclosure are not limited thereto.

Meanwhile, in the display device 100 according to an exemplary embodiment of the present disclosure, the plurality of light emitting elements 130 can be self-assembled on the substrate 110 using the plurality of low potential power supply lines VSS. The plurality of light emitting elements 130 can be dielectrically polarized by an electric field and have a polarity. Accordingly, the plurality of light emitting elements 130 can be moved or fixed in a specific direction by an electric field, and the plurality of light emitting elements 130 can be easily transferred to the display device 100 using this feature.

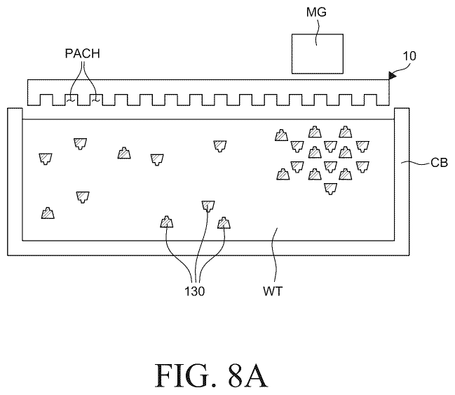

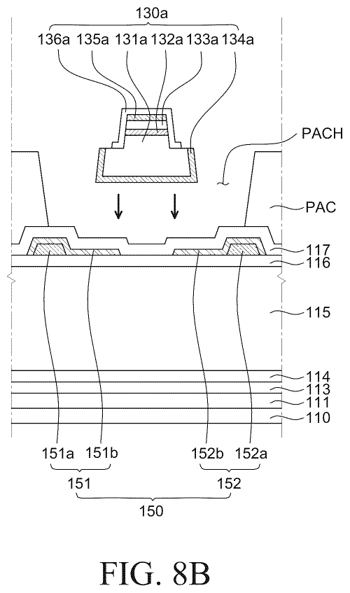

Hereinafter, a method of manufacturing the display device 100 according to an exemplary embodiment of the present disclosure will be described with reference to FIGS. 8A and 8B.

Particularly, FIGS. 8A and 8B are cross-sectional views illustrating a method of manufacturing the display device according to an exemplary embodiment of the present disclosure.

Referring to FIG. 8A, the light emitting elements 130 are put into a chamber CB filled with fluid WT. The fluid WT can include water or the like, and the chamber CB filled with the fluid WT can have an open top.

Next, a mother substrate 10 can be placed on the chamber CB filled with the light emitting elements 130. The mother substrate 10 is a substrate composed of a plurality of substrates 110 constituting the display device 100, and thereafter, the mother substrate 10 can be cut and separated into the plurality of substrates 110. When self-assembling the plurality of light emitting elements 130, the mother substrate 10 on which an organic layer PAC is additionally formed on the plurality of low potential power supply lines VSS and the third passivation layer 117 can be used.

Specifically, referring to FIG. 8B, the buffer layer 111, the gate insulating layer 112, the interlayer insulating layer 113, the first passivation layer 114, the first planarization layer 115, and the second passivation layer 116, along with the plurality of lines and the pixel circuit, are sequentially formed on the substrate 110. In addition, assembly electrodes 150 are formed on the second passivation layer 116.

The assembly electrodes 150 can function as the pair of low potential power supply lines VSS after manufacturing of the display device 100 is completed. During a manufacturing process of the display device 100, different voltages are applied to two assembly electrodes 150 adjacent to each other, and after a manufacturing process of the display device 100 is completed, the same low potential power supply voltage can be applied to the two adjacent assembly electrodes 150. The assembly electrode 150 has the same configuration as the low potential power supply line VSS, and will be referred to as the assembly electrode 150 in FIG. 8B for convenience of description.

The assembly electrodes 150 include a first assembly electrode 151 and a second assembly electrode 152.

The first assembly electrode 151 is disposed on the second passivation layer 116. The first assembly electrode 151 includes a first conductive layer 151a and a first cladding layer 151b covering the first conductive layer 151a.

The second assembly electrode 152 is disposed on the second passivation layer 116. The second assembly electrode 152 includes a second conductive layer 152a and a second cladding layer 152b covering the second conductive layer 152a.

Next, the third passivation layer 117 is formed on the assembly electrodes 150, and the organic layer PAC having openings PACH is formed on the third passivation layer 117. The opening PACH of the organic layer PAC can correspond to an area in which the light emitting element 130 is self-assembled. The opening PACH of the organic layer PAC can overlap the assembly electrodes 150. The organic layer PAC is removed after self-assembling of the light emitting element 130 is completed, and thus, does not exist in the display device 100 of which the manufacturing process has been completed.

Therefore, the plurality of light emitting elements 130, and the substrate 110 on which the organic layer PAC is formed as illustrated in FIG. 8B are put into the chamber CB filled with the fluid WT, and AC voltage can be applied to the assembly electrodes 150 to form an electric field. Accordingly, an electric field can be formed between the first assembly electrode 151 and the second assembly electrode 152.

The light emitting element 130 can be dielectrically polarized by an electric field and have a polarity. In addition, the dielectric polarized light emitting element 130 can be moved in a specific direction or fixed by dielectrophoresis (DEP), for example, an electric field. For example, the dielectric polarized light emitting element 130 can be moved in a direction perpendicular to the substrate 100 by dielectrophoresis (DEP), but embodiments of the present disclosure are not limited thereto. Accordingly, the plurality of light emitting elements 130 can be self-assembled on the assembly electrodes 150 using dielectrophoresis.

Finally, when the self-assembling of the light emitting elements 130 is completed, the organic layer PAC is removed and other components such as the adhesive layer AD, the contact electrodes CE, the second planarization layer 118, the fourth passivation layer 119, and the pixel electrodes PE can be formed, whereby the manufacturing process of the display device 100 can be completed.

Meanwhile, uniformity of the electric field can vary according to distribution of areas in which a plurality of the openings PACH of the organic layer PAC and a plurality of the assembly electrodes 150 are formed. For example, when the areas in which the plurality of openings PACH and the plurality of assembly electrodes 150 are disposed are uniformly distributed at regular intervals, an electric field is uniformly formed in each of the openings PACH, so that a self-assembling rate of the light emitting elements 130 can be improved. On the other hand, when the areas in which the openings PACH and the plurality of assembly electrodes 150 are disposed are non-uniformly distributed, electric fields can be non-uniformly formed in the openings PACH, so that assembling failure of the light emitting elements 130 can occur. Accordingly, in the display device 100 according to an exemplary embodiment of the present disclosure, by extending the areas in which the plurality of assembly electrodes 150 and the openings PACH are formed from the display area AA to the dummy area DA surrounding the display area AA, it is possible to form a uniform electric field even in the entirety of display area AA, in particular, even in an outermost portion of the display area AA. For example, the area in which the plurality of openings PACH are disposed can be formed to be larger than the display area AA so that the openings PACH of the outermost portion of the display area AA in which electric fields are non-uniformly formed are not disposed in the display area AA. Accordingly, the self-assembling rate of the light emitting elements 130 in the display area AA can be improved by disposing only the openings PACH in which electric fields are uniformly formed in the display area AA.

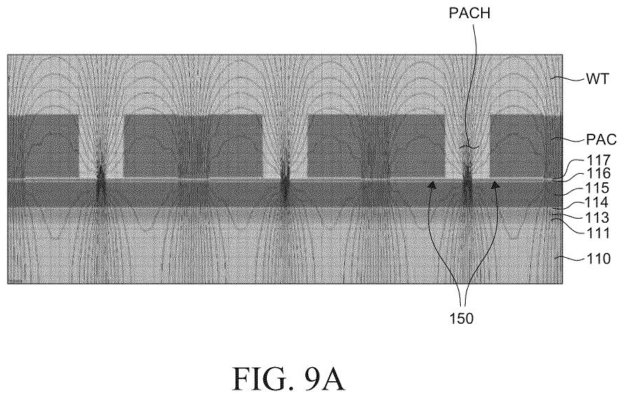

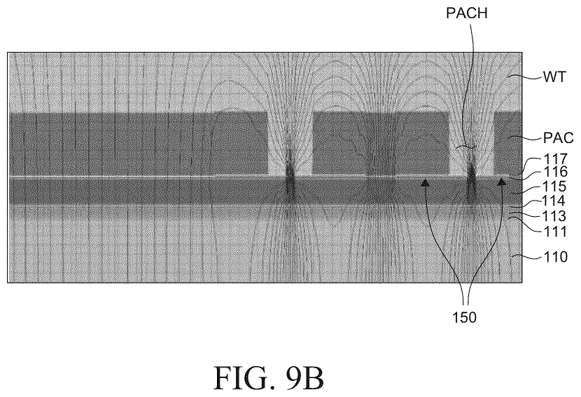

Hereinafter, distribution of electric fields according to positions of the plurality of openings PACH and the plurality of assembly electrodes 150 will be described with reference to FIGS. 9A and 9B.

FIGS. 9A and 9B are examples of simulation results obtained by measuring electric fields formed by a plurality of assembly electrodes. Specifically, FIG. 9A is a simulation result obtained by measuring electric fields formed by the plurality of assembly electrodes 150 when the plurality of openings PACH and the plurality of assembly electrodes 150 are uniformly distributed. FIG. 9B is a simulation result obtained by measuring electric fields formed by the plurality of assembly electrodes 150 when the plurality of openings PACH and the plurality of assembly electrodes 150 are non-uniformly distributed.

Referring to FIG. 9A, it can be confirmed that electric fields are uniformly formed in a symmetrical structure when the plurality of openings PACH and the plurality of assembly electrodes 150 are uniformly distributed at regular intervals on the substrate 110. The electric fields formed in each of the assembly electrodes 150 on a left side and a right side of the opening PACH can form a symmetrical structure. Accordingly, it can be confirmed that equipotential lines of the electric fields are concentrated in areas corresponding to the openings PACH. In this case, the plurality of light emitting elements 130 can be more easily self-assembled in the openings PACH.

Referring to FIG. 9B, it can be confirmed that electric fields are formed in an asymmetrical structure when the plurality of openings PACH and the plurality of assembly electrodes 150 are non-uniformly distributed on the substrate 110. For example, the openings PACH and the assembly electrodes 150 are not formed in a left area of FIG. 9B, so that electric fields are not formed. The openings PACH and the assembly electrodes 150 are disposed in a center area and a right area of FIG. 9B, so that electric fields are formed. In particular, the assembly electrode 150 is not formed on a left side of the opening PACH and the assembly electrodes 150 that are disposed in the central area, and the assembly electrode 150 is formed only on the right side of the opening PACH and the assembly electrodes 150 that are disposed in the central area, so that electric fields can be formed in an asymmetric structure in the opening PACH of the central area. In this case, the self-assembling rate of the light emitting element 130 is reduced by the electric fields of the asymmetric structure, and even if the light emitting element 130 is self-assembled in the opening PACH, it can be tilted or assembled out of position.

Thus, in an outermost opening PACH among the plurality of openings PACH, non-uniformity in electric field can occur, resulting in a decrease in self-assembling rate. For example, if the plurality of openings PACH and the plurality of assembly electrodes 150 are formed only in the display area AA, areas in which the plurality of openings PACH and the plurality of assembly electrodes 150 are disposed may not be uniformly distributed in the outermost portion of the display area AA, electric fields having an asymmetric structure as illustrated in FIG. 9B can be formed. Therefore, if the plurality of openings PACH and the plurality of assembly electrodes 150 are formed only in the display area AA, electric fields can be non-uniformly formed in an outer area of the display area AA, resulting in poor assembling of the light emitting elements 130.

Accordingly, in the display device 100 according to an exemplary embodiment of the present disclosure, the plurality of openings PACH and the plurality of assembly electrodes 150 are additionally formed in the dummy area DA surrounding the display area AA, so that self-assembling issues/defects of the plurality of light emitting elements 130 in the outermost portion of the display area AA can be reduced or minimized. Since the area in which the plurality of openings PACH and the plurality of assembly electrodes 150 are formed is formed even in the dummy area DA outside the display area AA, eventually, the plurality of openings PACH and the plurality of assembly electrodes 150 can be uniformly distributed in the entirety of the display area AA. For example, since the area in which the plurality of openings PACH and the plurality of assembly electrodes 150 are formed is larger than the display area AA, can be included in the area in which electric fields are uniformly formed. Therefore, as illustrated in FIG. 9A, electric fields of a symmetric structure can be formed in the entirety of the display area AA, and the self-assembling rate of the light emitting elements 130 can be improved in the entirety of the display area AA.

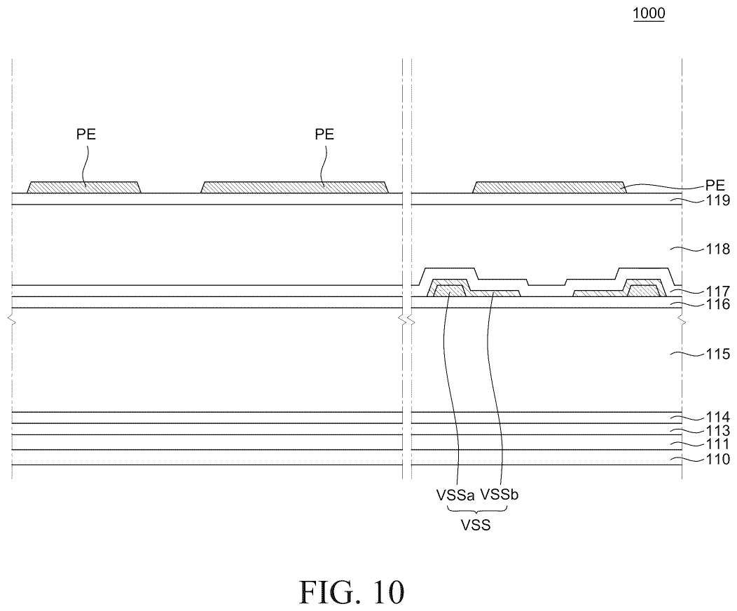

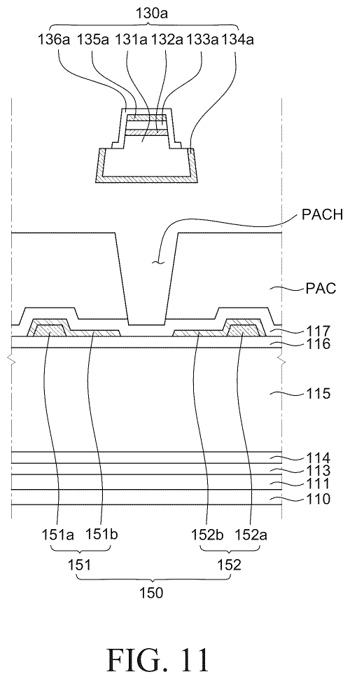

FIG. 10 is a cross-sectional view of a dummy area of a display device according to another exemplary embodiment of the present disclosure. FIG. 11 is a cross-sectional view for explaining a method of manufacturing the display device according to another exemplary embodiment of the present disclosure. Since a display device 1000 of FIGS. 10 and 11 is substantially identical to the display device 100 of FIGS. 1 to 7 except that it does not include the plurality of light emitting elements 130 and has a difference in terms of the opening PACH of the organic layer PAC, redundant descriptions thereof will be omitted.

Referring to FIG. 10, in the plurality of dummy sub-pixels DSP of the dummy area DA, the plurality of light emitting elements 130 are not disposed, and the plurality of lines including the plurality of scan lines SL, the plurality of data lines DL, the plurality of reference lines RL, the plurality of high potential power supply lines VDD, and the plurality of low potential power supply lines VSS, and the plurality of pixel electrodes PE are disposed. In this case, only the third passivation layer 117, the second planarization layer 118, the fourth passivation layer 119, and the plurality of pixel electrodes PE can be disposed on the plurality of low potential power supply lines VSS.

Referring to FIG. 11, in the display device 1000 according to another exemplary embodiment of the present disclosure, when the light emitting element 130 (e.g., 130a) is self-assembled, the opening PACH having a size smaller than that of the light emitting element 130 can be formed in the organic layer PAC corresponding to the dummy area DA to thereby prevent the light emitting element 130 from being assembled in the dummy area DA.

Specifically, the organic layer PAC includes the plurality of openings PACH, and a size or shape of each of the plurality of openings PACH can vary depending on the area in which the opening PACH is disposed. For example, the opening PACH of the organic layer PAC disposed in the display area AA can have a size larger than that of the light emitting element 130 so that the light emitting element 130 can be seated in the opening PACH. The plurality of openings PACH disposed in the display area AA can have a width greater than that of the light emitting elements 130 so that the light emitting elements 130 can be self-assembled in the openings PACH. Further, the opening PACH of the display area AA can have a shape corresponding to a planar shape of the light emitting element 130 so that the light emitting element 130 can be seated therein. Accordingly, the light emitting element 130 can be self-assembled in the opening PACH of the display area AA by electric fields formed by the plurality of assembly electrodes 150.

For example, the opening PACH of the organic layer PAC disposed in the dummy area DA of the non-display area NA can have a size smaller than that of the light emitting element 130 to prevent the light emitting element 130 from being seated in the opening PACH. The plurality of openings PACH disposed in the dummy area DA can have a width smaller than that of the light emitting elements 130. In the dummy area DA, the opening PACH has a size smaller than that of the light emitting element 130, so the light emitting element 130 cannot be seated in the opening PACH. Further, the opening PACH of the dummy area DA can have a shape different from the planar shape of the light emitting element 130 to prevent the light emitting element 130 from being seated in the opening PACH. When the planar shape of the light emitting element 130 is circular, the opening PACH of the dummy area DA can be formed in a quadrangular shape to prevent self-assembling of the light emitting element 130 in the dummy area DA.

In this case, the opening PACH disposed in the display area AA can be referred to as a first opening, and the opening PACH disposed in the dummy area DA can be referred to as a second opening.

Therefore, in the display device 1000 according to another exemplary embodiment of the present disclosure, the light emitting element 130 is not self-assembled in the dummy area DA, so that a manufacturing cost can be reduced. The plurality of assembly electrodes 150 and openings PACH are disposed in the dummy area DA to form electric fields of a symmetrical structure in the outermost portion of the display area AA, but the openings PACH of the organic layer PAC having a smaller size than and/or a different shape from that of the light emitting elements 130 are formed in the dummy area DA, so that the plurality of light emitting elements 130 cannot or may not be self-assembled in the dummy area DA. Therefore, the light emitting elements 130 are self-assembled only in the display area AA among the dummy area DA and the display area AA, so that a manufacturing cost can be reduced.

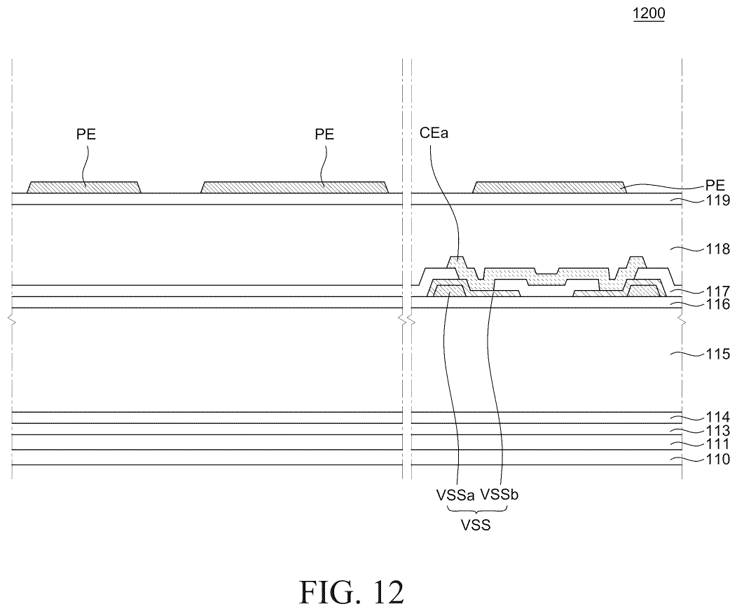

FIG. 12 is a cross-sectional view of a dummy area of a display device according to still another exemplary embodiment of the present disclosure. Since other configurations of a display device 1200 of FIG. 12 are substantially identical to those of the display device 1000 of FIGS. 10 and 11 except that it further includes dummy contact electrodes CEa, redundant descriptions thereof will be omitted or may be briefly provided.

Referring to FIG. 12, the dummy contact electrode CEa is disposed in each of the plurality of dummy sub-pixels DSP of the dummy area DA. The dummy contact electrode CEa is disposed on the third passivation layer 117 to overlap the pair of low potential power supply lines VSS. The dummy contact electrode CEa can be formed together with forming of the contact electrodes CE of the display area AA.

The dummy contact electrode CEa of the dummy area DA can be electrically connected to the pair of low potential power supply lines VSS through the contact hole formed in the third passivation layer 117. Accordingly, the pair of low potential power supply lines VSS to which the same low potential power supply voltage is applied can be electrically connected to each other through the dummy contact electrode CEa.

Meanwhile, although FIG. 12 illustrates that one dummy contact electrode CEa is disposed in one dummy sub-pixel DSP, the dummy contact electrodes CEa disposed in each of the plurality of dummy sub-pixels DSP can be connected to each other. In this case, the plurality of low potential power supply lines VSS disposed in each of the plurality of dummy sub-pixels DSP can be electrically connected to each other through the dummy contact electrodes CEa.

Further, although FIG. 12 illustrates that the light emitting elements 130 are not transferred to the dummy sub-pixel DSP, the light emitting elements 130 can be disposed together with the dummy contact electrode CEa, but embodiments of the present disclosure are not limited thereto.

Therefore, in the display device 1200 according to still another exemplary embodiment of the present disclosure, the plurality of low potential power supply lines VSS are connected to each other by forming the dummy contact electrodes CEa, so that resistance of the plurality of low potential power supply lines VSS can be reduced or minimized. Specifically, when forming the contact electrodes CE in the plurality of sub-pixels SP, the dummy contact electrodes CEa can also be formed in the dummy sub-pixels DSP. In this case, the dummy contact electrode CEa can be connected to at least two or more low potential power supply lines VSS through the contact hole of the third passivation layer 117. Accordingly, as the plurality of low potential power supply lines VSS are connected to each other through the dummy contact electrode CEa, an overall resistance of the plurality of low potential power supply lines VSS can be reduced or minimized and variations in low potential power supply voltage can be reduced. Therefore, in the display device 1200 according to still another exemplary embodiment of the present disclosure, the dummy contact electrodes CEa are formed in the dummy area DA in which the plurality of low potential power supply lines VSS are disposed, so that the plurality of low potential power supply lines VSS are connected in a mesh structure, so that resistance of the low potential power supply line VSS can be reduced or minimized and luminance uniformity can be improved.

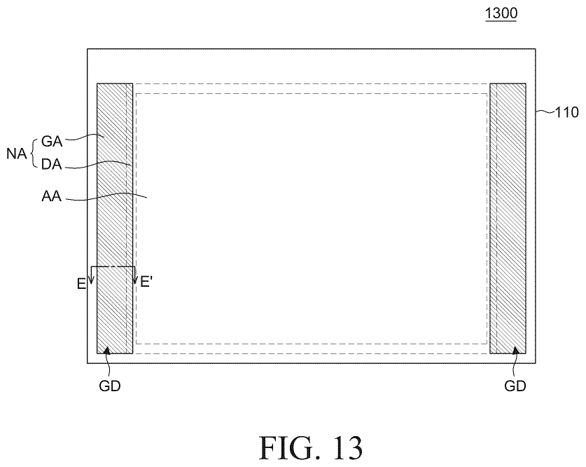

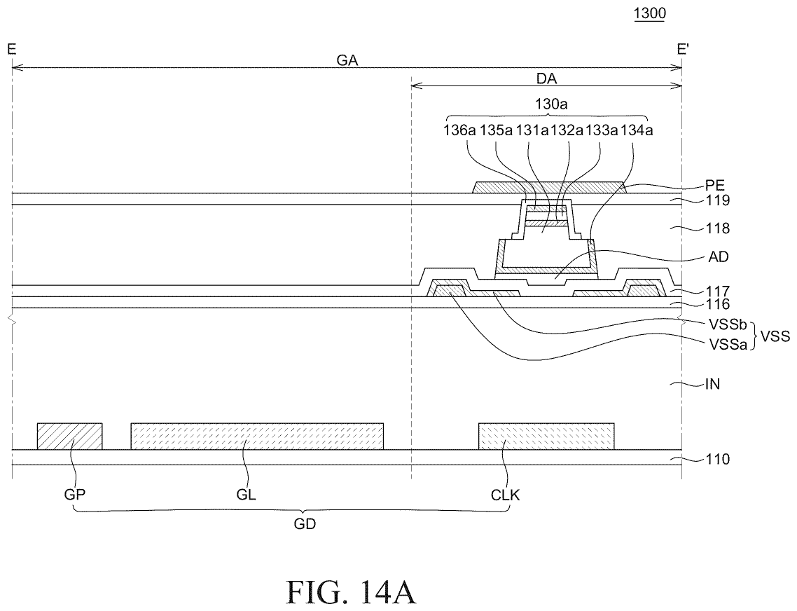

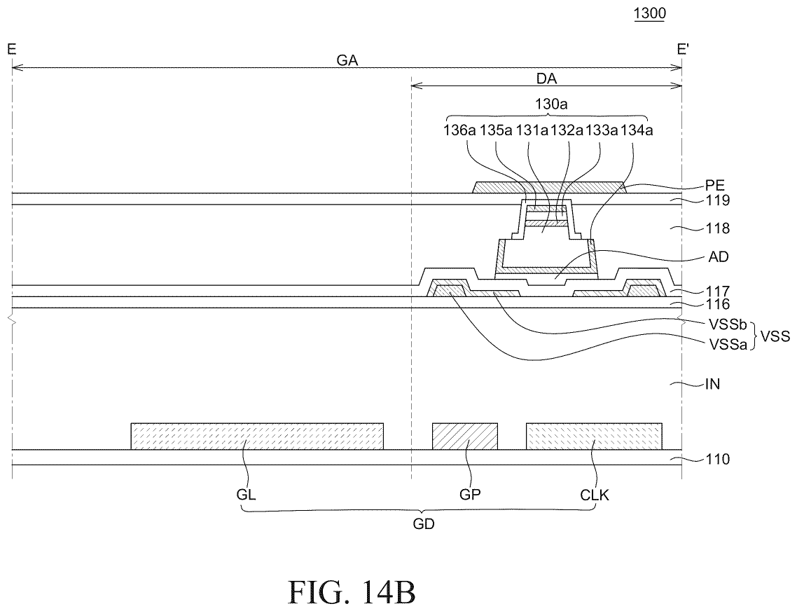

FIG. 13 is a plan view of a display panel of a display device 1300 according to still another exemplary embodiment of the present disclosure. FIGS. 14A and 14B are cross-sectional views taken along line E-E′ of FIG. 13. Since other configurations of the display device 1300 of FIG. 13, FIG. 14A and FIG. 14B are substantially identical to those of the display device 100 of FIGS. 1 to 7 except that it has a difference in terms of a gate driving area GA, redundant descriptions thereof will be omitted or may be briefly discussed. In FIGS. 14A and 14B, for convenience of description, the buffer layer 111, the gate insulating layer 112, the interlayer insulating layer 113, the first passivation layer 114, and the first planarization layer 115 are simply illustrated as one insulating layer, and the gate driver GD is schematically illustrated.

Referring to FIG. 13, the gate driving area GA and the dummy area DA of the display panel PN can at least partially overlap each other. The gate driver GD of the gate driving area GA can overlap the plurality of dummy sub-pixels DSP of the dummy area DA.

The gate driver GD disposed in the gate driving area GA includes a logic unit GL, a power supply unit GP, and a clock unit CLK.

The logic unit GL can include a plurality of stages including a plurality of transistors and a storage capacitor Cst to generate scan signals. The plurality of stages of the logic unit GL are cascade-connected to generate a scan signal based on a start signal or a scan signal of a previous stage, and sequentially output the scan signal to each of the plurality of scan lines SL.

The power supply unit GP includes a power supply line for applying a power supply voltage for driving the logic unit GL to the logic unit GL. For example, the power supply unit GP can include a gate low voltage line and a gate high voltage line, but embodiments of the present disclosure are not limited thereto.

The clock unit CLK includes a plurality of clock signal lines for supplying clock signals to the logic unit GL. The plurality of clock signal lines of the clock unit CLK can be connected to each of the plurality of stages of the logic unit GL and supply a plurality of clock signals to the logic unit GL. Accordingly, the logic unit GL can generate and output a scan signal based on a timing of the clock signal.

Meanwhile, the logic unit GL, the power supply unit GP, and the clock unit CLK of the gate driver GD can be formed together with forming the plurality of transistors and the plurality of lines in the display area AA. For example, elements such as lines or transistors included in the logic unit GL, the power supply unit GP, and the clock unit CLK can be formed through the same process as that of the scan lines SL, the data lines DL, the high potential power supply lines VDD, the first transistor T1, the second transistor T2, the third transistor T3, and the storage capacitor Cst. Thus, a majority of components constituting the gate driver GD can be disposed under the second passivation layer 116.

Therefore, in the display device 1300 according to still another exemplary embodiment of the present disclosure, at least a portion of the gate driver GD is disposed in an empty space below the low potential power supply line VSS of the dummy sub-pixel DSP, so that an area of the non-display area NA can be reduced or minimized. At least a portion of the plurality of lines included in the gate driver GD can be disposed in the dummy area DA.

For example, referring to FIG. 14A, in the gate driver GD, the clock unit CLK including a plurality of clock signal lines can be disposed in the dummy area DA. The clock unit CLK can be disposed in an empty space below the light emitting element 130. In the dummy area DA, the plurality of clock signal lines of the clock unit CLK can be disposed between a plurality of respective insulating layers including the buffer layer 111, the gate insulating layer 112, the interlayer insulating layer 113, the first passivation layer 114, the first planarization layer 115, and the second planarization layer 118 or between the plurality of insulating layers and the substrate 110, but embodiments of the present disclosure are not limited thereto.

For another example, referring to FIG. 14B, the clock unit CLK and the power supply unit GP of the gate driver GD can be disposed in the dummy area DA. The power supply unit GP and the clock unit CLK can be disposed in an empty space below the light emitting element 130. In the dummy area DA, the plurality of clock signal lines of the clock unit CLK and the lines of the power supply unit GP can be disposed between the plurality of respective insulating layers or between the plurality of insulating layers and the substrate 110, but embodiments of the present disclosure are not limited thereto.

Accordingly, in the display device 1300 according to still another exemplary embodiment of the present disclosure, the gate driver GD can be disposed in the empty space below the light emitting element 130 in the dummy area DA to reduce or minimize the area of the non-display area NA. In the dummy area DA, only the low potential power supply line VSS or the like for self-assembling of the light emitting element 130 is disposed, and a pixel circuit including the first transistor T1, the second transistor T2, the third transistor T3, the storage capacitor Cst, and the like is not disposed. Accordingly, by disposing at least a portion of the gate driver GD in an empty space of the dummy area DA where the pixel circuit is not disposed, an overall area of the non-display area NA can be reduced or minimized. For example, the lines of the clock unit CLK or the power supply unit GP of the gate driver GD can be disposed in an empty space between the substrate 110 and the light emitting element 130 in the dummy area DA, but embodiments of the present disclosure are not limited thereto. Thus, the gate driving area GA and the dummy area DA partially overlap each other in the non-display area NA, so that the area of the non-display area NA can be reduced or minimized.

The exemplary embodiments of the present disclosure can also be described as follows:

According to an aspect of the present disclosure, there is provided a display device. The display device includes a display panel including a display area and a dummy area extending from the display area, a plurality of sub-pixels disposed in the display area, a plurality of dummy sub-pixels disposed in the dummy area, a pixel circuit disposed in the plurality of sub-pixels, and at least a pair of low potential power supply lines disposed in each of the plurality of sub-pixels and the plurality of dummy sub-pixels.

The pixel circuit may not be disposed in the plurality of dummy sub-pixels.

The display device can further comprise first pad electrodes disposed on a front surface of the display panel and transmitting signals to the plurality of sub-pixels; second pad electrodes disposed on a rear surface of the display panel and connected to driving components for driving the plurality of sub-pixels; and side lines electrically connect the first pad electrodes and second pad electrodes.

The display device can further include light emitting elements disposed on the at least pair of low potential power supply lines in the plurality of sub-pixels and the plurality of dummy sub-pixels, and pixel electrodes disposed on the plurality of light emitting elements in the plurality of sub-pixels and the plurality of dummy sub-pixels. The light emitting elements disposed in the plurality of sub-pixels can be electrically connected to the pixel electrodes and the pixel circuit.

The pixel electrodes disposed in the plurality of dummy sub-pixels can be floating.

The display device can further include an insulating layer disposed between the light emitting elements and the pixel electrodes in the display area and the dummy area. The light emitting elements disposed in the plurality of sub-pixels can be exposed from the insulating layer and electrically connected to the pixel electrodes, and the light emitting elements disposed in the plurality of dummy sub-pixels can be separated from the pixel electrodes by the insulating layer.

The light emitting elements disposed in the plurality of sub-pixels can be electrically connected to the at least pair of low potential power supply lines, and the light emitting elements disposed in the plurality of dummy sub-pixels can be separated from the at least pair of low potential power supply lines.

The display device can further include a passivation layer disposed between the light emitting elements and the at least pair of low potential power supply lines in the display area and the dummy area, and contact electrodes disposed on the passivation layer in each of the plurality of sub-pixels and the plurality of dummy sub-pixels to contact at least a portion of the light emitting elements. The contact electrode disposed in each of the plurality of sub-pixels can contact the at least pair of low potential power supply lines through a contact hole of the passivation layer.

The display device can further include light emitting elements disposed on the at least pair of low potential power supply lines in the plurality of sub-pixels, and pixel electrodes disposed on each of the plurality of sub-pixels and the plurality of dummy sub-pixels. The pixel electrodes disposed in the plurality of sub-pixels can be electrically connected to the light emitting elements.

The display device can further include a passivation layer disposed on the at least pair of low potential power supply lines in the display area and the dummy area, contact electrodes disposed on the passivation layer in the plurality of sub-pixels, and dummy contact electrodes disposed on the passivation layer in the plurality of dummy sub-pixels.

Each of the contact electrode and the dummy contact electrode can be electrically connected to the at least pair of low potential power lines through a contact hole of the passivation layer.

The display panel can further include a gate driving area at least partially overlapping the dummy area. The display device can further include a gate driver disposed in the gate driving area, at least a portion of the gate driver can overlap the dummy area.

The gate driver can include a logic unit generating a scan signal and outputting the scan signal to each of the plurality of sub-pixels, a power supply unit including a power supply line for applying a power supply voltage to the logic unit, and a clock unit including a plurality of clock signal lines for supplying a clock signal to the logic unit. At least one the power supply unit and the clock unit can be disposed between the display panel and the at least pair of low potential power supply lines in the dummy area.

According to an aspect of the present disclosure, there is provided a method of manufacturing a display device. The method of manufacturing the display device include forming at least a pair of assembly electrodes in each of a plurality of sub-pixels in an display area of a display panel and a plurality of dummy sub-pixels in a dummy area extending from the display area, forming an organic layer having a plurality of openings on the at least pair of assembly electrodes in each of the plurality of sub-pixels and the plurality of dummy sub-pixels, and self-assembling a light emitting element in an opening disposed in each of the plurality of sub-pixels among the plurality of openings.

The self-assembling of the light emitting element includes forming electric fields by applying a voltage to the at least pair of assembly electrodes disposed in the display area and the dummy area.

The method can further include self-assembling the light emitting element in an opening disposed in each of the plurality of dummy sub-pixels among the plurality of openings, and forming contact electrodes electrically connecting the light emitting element and the at least pair of assembly electrodes in the plurality of sub-pixels. The light emitting element self-assembled in the plurality of dummy sub-pixels can be insulated from the at least pair of assembly electrodes.

The method can further include forming an insulating layer covering the light emitting elements in the plurality of sub-pixels and the plurality of dummy sub-pixels, and forming pixel electrodes on the insulating layer in the plurality of sub-pixels and the plurality of dummy sub-pixels. The pixel electrodes formed in the plurality of sub-pixels can be electrically connected to the light emitting element through a contact hole of the insulating layer, and the pixel electrodes formed in the plurality of dummy sub-pixels can be floating.

The plurality of openings of the organic layer can include a first opening disposed in each of the plurality of sub-pixels and having a width greater than that of the light emitting element, and a second opening disposed in each of the plurality of dummy sub-pixels and having a width smaller than that of the light emitting element.

The plurality of openings of the organic layer can include a first opening disposed in each of the plurality of sub-pixels, and a second opening disposed in each of the plurality of dummy sub-pixels, wherein a shape of the first opening and a shape of the second opening are different.

The shape of the first opening is same to a shape of the light emitting element, and the shape of the second opening is different from the shape of the light emitting element.

Although the exemplary embodiments of the present disclosure have been described in detail with reference to the accompanying drawings, the present disclosure is not limited thereto and can be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a display panel including a display area and a dummy area extending from the display area;
a plurality of sub-pixels disposed in the display area;
a plurality of dummy sub-pixels disposed in the dummy area;
a pixel circuit disposed in the plurality of sub-pixels; and
at least a pair of low potential power supply lines disposed in each of the plurality of sub-pixels and the plurality of dummy sub-pixels.

2. The display device of claim 1, wherein the pixel circuit is not disposed in the plurality of dummy sub-pixels.

3. The display device of claim 1, further comprising:
first pad electrodes disposed on a front surface of the display panel and configured to transmit signals to the plurality of sub-pixels;
second pad electrodes disposed on a rear surface of the display panel and connected to driving components for driving the plurality of sub-pixels; and
side lines configured to electrically connect the first pad electrodes and second pad electrodes.

4. The display device of claim 1, further comprising:
light emitting elements disposed on the at least pair of low potential power supply lines in the plurality of sub-pixels and the plurality of dummy sub-pixels; and
pixel electrodes disposed on the light emitting elements in the plurality of sub-pixels and the plurality of dummy sub-pixels,
wherein the light emitting elements disposed in the plurality of sub-pixels are electrically connected to the pixel electrodes and the pixel circuit.

5. The display device of claim 4, wherein the pixel electrodes disposed in the plurality of dummy sub-pixels are floating.

6. The display device of claim 4, further comprising:
an insulating layer disposed between the light emitting elements and the pixel electrodes in the display area and the dummy area,
wherein the light emitting elements disposed in the plurality of sub-pixels are exposed from the insulating layer and electrically connected to the pixel electrodes, and
the light emitting elements disposed in the plurality of dummy sub-pixels are separated from the pixel electrodes by the insulating layer.

7. The display device of claim 4, wherein the light emitting elements disposed in the plurality of sub-pixels are electrically connected to the at least pair of low potential power supply lines, and
the light emitting elements disposed in the plurality of dummy sub-pixels are separated from the at least pair of low potential power supply lines.

8. The display device of claim 7, further comprising:
a passivation layer disposed between the light emitting elements and the at least pair of low potential power supply lines in the display area and the dummy area; and
contact electrodes disposed on the passivation layer in each of the plurality of sub-pixels and the plurality of dummy sub-pixels to contact at least a portion of the light emitting elements,
wherein the contact electrode disposed in each of the plurality of sub-pixels contacts the at least pair of low potential power supply lines through a contact hole of the passivation layer.

9. The display device of claim 1, further comprising:
light emitting elements disposed on the at least pair of low potential power supply lines in the plurality of sub-pixels; and
pixel electrodes disposed on each of the plurality of sub-pixels and the plurality of dummy sub-pixels;
wherein the pixel electrodes disposed in the plurality of sub-pixels are electrically connected to the light emitting elements.

10. The display device of claim 1, further comprising:
a passivation layer disposed on the at least pair of low potential power supply lines in the display area and the dummy area;
contact electrodes disposed on the passivation layer in the plurality of sub-pixels; and
dummy contact electrodes disposed on the passivation layer in the plurality of dummy sub-pixels.

11. The display device of claim 10, wherein each of the contact electrode and the dummy contact electrode is electrically connected to the at least pair of low potential power lines through a contact hole of the passivation layer.

12. The display device of claim 1, wherein the display panel further includes a gate driving area at least partially overlapping the dummy area,
wherein the display device further comprises a gate driver disposed in the gate driving area, and
wherein at least a portion of the gate driver overlaps the dummy area.

13. The display device of claim 12, wherein the gate driver includes:
a logic unit configured to generate a scan signal and output the scan signal to each of the plurality of sub-pixels;
a power supply unit including a power supply line for applying a power supply voltage to the logic unit; and
a clock unit including a plurality of clock signal lines for supplying a clock signal to the logic unit,
wherein at least one the power supply unit and the clock unit is disposed between the display panel and the at least pair of low potential power supply lines in the dummy area.

14. A method of manufacturing a display device including a display panel having a display area and a dummy area, the method comprising:
forming at least a pair of assembly electrodes in each of a plurality of sub-pixels in the display area and a plurality of dummy sub-pixels in the dummy area extending from the display area;
forming an organic layer having a plurality of openings on the at least pair of assembly electrodes in each of the plurality of sub-pixels and the plurality of dummy sub-pixels; and
self-assembling a light emitting element in an opening disposed in each of the plurality of sub-pixels among the plurality of openings.

15. The method of claim 14, wherein the self-assembling of the light emitting element includes forming electric fields by applying a voltage to the at least pair of assembly electrodes disposed in the display area and the dummy area.

16. The method of claim 14, further comprising:
self-assembling the light emitting element in an opening disposed in each of the plurality of dummy sub-pixels among the plurality of openings; and
forming contact electrodes electrically connecting the light emitting element and the at least pair of assembly electrodes in the plurality of sub-pixels,
wherein the light emitting element that is self-assembled in the plurality of dummy sub-pixels is insulated from the at least pair of assembly electrodes.

17. The method of claim 16, further comprising:
forming an insulating layer covering the light emitting elements in the plurality of sub-pixels and the plurality of dummy sub-pixels; and
forming pixel electrodes on the insulating layer in the plurality of sub-pixels and the plurality of dummy sub-pixels,
wherein the pixel electrodes formed in the plurality of sub-pixels are electrically connected to the light emitting element through a contact hole of the insulating layer;
wherein the pixel electrodes formed in the plurality of dummy sub-pixels are floating.

18. The method of claim 14, wherein the plurality of openings of the organic layer include:
a first opening disposed in each of the plurality of sub-pixels, and having a width greater than a width of the light emitting element; and
a second opening disposed in each of the plurality of dummy sub-pixels, and having a width smaller than the width of the light emitting element.

19. The method of claim 14, wherein the plurality of openings of the organic layer include:
a first opening disposed in each of the plurality of sub-pixels; and
a second opening disposed in each of the plurality of dummy sub-pixels,
wherein a shape of the first opening and a shape of the second opening are different from each other.

20. The method of claim 19, wherein the shape of the first opening is substantially same as a shape of the light emitting element, and the shape of the second opening is different from the shape of the light emitting element.
